(19) United States
(12) Patent Application Publication
(10) Pub. No.: US 2026/0047285 A1
(43) Pub. Date: Feb. 12, 2026

(54) DISPLAY DEVICE, ELECTRONIC DEVICE AND MANUFACTURING METHOD OF THE SAME

(71) Applicant: Samsung Display Co., Ltd., Yongin-si (KR)

(72) Inventors: Kyung-Tae KIM, Yongin-si (KR); JUN HYUNG LIM, Yongin-si (KR); CHULWON PARK, Yongin-si (KR); SANGWOO SOHN, Yongin-si (KR); Hyunjun JEONG, Yongin-si (KR)

(73) Assignee: Samsung Display Co., Ltd., Yongin-si (KR)

(21) Appl. No.: 19/234,522

(22) Filed: Jun. 11, 2025

(30) Foreign Application Priority Data
Aug. 6, 2024 (KR) 10-2024-0104615

(51) Int. Cl. H10K 59/124; G09G 3/3233; H10K 59/12; H10K 59/121

(52) U.S. Cl. CPC H10K 59/124; H10K 59/1201; H10K 59/1213; G09G 3/3233; G09G 2300/0426; G09G 2300/0819; G09G 2300/0852; G09G 2300/0861; G09G 2310/0286; G09G 2310/08

(57) ABSTRACT

A display device includes a circuit layer disposed on a base layer and including a buffer layer including a plurality of layers and a plurality of pixel transistors disposed on the buffer layer, and a display layer disposed on the circuit layer and including a light-emitting element. An upper layer forming a top of the plurality of layers included in the buffer layer includes a first portion overlapping a first semiconductor pattern of a first pixel transistor among the plurality of pixel transistors in a plan view, and a second portion overlapping a second semiconductor pattern of a second pixel transistor among the plurality of pixel transistors in a plan view. A first thickness of the first portion and a second thickness of the second portion are different from each other.

### CROSS-REFERENCE TO RELATED APPLICATION(S)

This U.S. application claims priority to and the benefits of Korean Patent Application No. 10-2024-0104615 under 35 U.S. C. § 119, filed on Aug. 6, 2024, in the Korean Intellectual Property Office, the entire contents of which are incorporated herein by reference.

### BACKGROUND

### 1. Technical Field

The disclosure herein relates to a display device with improved reliability and a manufacturing method of the same.

### 2. Description of the Related Art

A display device includes a plurality of pixels and driving circuits (e.g., a scan driving circuit and a data driving circuit) for controlling the plurality of pixels. Each of the plurality of pixels includes a display element and a pixel circuit for controlling the display element. The pixel circuit may include a plurality of transistors electrically connected to each other.

The plurality of transistors may include silicon semiconductor or a metal oxide semiconductor.

### SUMMARY

The disclosure provides a display device including a driving transistor having a wide driving range and a manufacturing method of the same.

According to an embodiment of the disclosure, a display device may include a circuit layer disposed on a base layer and including a buffer layer including a plurality of layers and a plurality of pixel transistors disposed on the buffer layer, and a display layer disposed on the circuit layer and including a light-emitting element. An upper layer forming a top of the plurality of layers included in the buffer layer may include a first portion overlapping a first semiconductor pattern of a first pixel transistor among the plurality of pixel transistors in a plan view, and a second portion overlapping a second semiconductor pattern of a second pixel transistor among the plurality of pixel transistors in a plan view. A first thickness of the first portion and a second thickness of the second portion may be different from each other.

In an embodiment of the disclosure, the buffer layer may further include a lower layer disposed on the base layer, and an intermediate layer disposed on the lower layer.

In an embodiment of the disclosure, the lower layer may include a third portion overlapping the first semiconductor pattern in a plan view, and a fourth portion overlapping the second semiconductor pattern in a plan view. A third thickness of the third portion and a fourth thickness of the fourth portion may be different from each other.

In an embodiment of the disclosure, the first thickness may be greater than the third thickness, and the second thickness may be less than the fourth thickness.

In an embodiment of the disclosure, a sum of the first thickness and the third thickness and a sum of the second thickness and the fourth thickness may be same.

In an embodiment of the disclosure, a thickness of the intermediate layer may be greater than a thickness of each of the lower layer and the upper layer.

In an embodiment of the disclosure, each of the lower layer and the upper layer may include silicon oxide, and the intermediate layer may include silicon nitride.

In an embodiment of the disclosure, the circuit layer may further include a barrier layer on the base layer and a conductive layer on the barrier layer, and the conductive layer may overlap the first semiconductor pattern in a plan view.

In an embodiment of the disclosure, the display device may further include a lower conductive layer between the base layer and the barrier layer. The lower conductive layer may overlap the conductive layer in a plan view.

In an embodiment of the disclosure, the base layer may be divided into a display area and a non-display area disposed on at least one side of the display area, and the circuit layer may further include a transistor in the non-display area.

In an embodiment of the disclosure, the upper layer may further include a sub-section overlapping a semiconductor pattern of the transistor in a plan view, and the first thickness of the first portion and a thickness of the sub-section may be different from each other.

In an embodiment of the disclosure, the circuit layer may further include a conductive layer on the base layer, and the conductive layer may overlap the semiconductor pattern in a plan view.

In an embodiment of the disclosure, the first pixel transistor may be a driving transistor, and the second pixel transistor may be a switching transistor.

In an embodiment of the disclosure, the first thickness may be greater than the second thickness, the first thickness may be in a range of about 500 Å to about 800 Å , and the second thickness may be in a range of about 200 Å to about 500 Å.

In an embodiment of the disclosure, each of the first semiconductor pattern and the second semiconductor pattern may include an oxide semiconductor.

In an embodiment of the disclosure, an electronic device may include a display device, an electronic module overlapping the display device in a plan view; and a housing accommodating the display device. The display device may include a circuit layer disposed on a base layer and comprising a buffer layer comprising a plurality of layers and a plurality of pixel transistors disposed on the buffer layer, and a display layer disposed on the circuit layer and comprising a light-emitting element. An upper layer forming a top of the plurality of layers comprised in the buffer layer may include a first portion overlapping a first semiconductor pattern of a first pixel transistor among the plurality of pixel transistors in a plan view, and a second portion overlapping a second semiconductor pattern of a second pixel transistor among the plurality of pixel transistors in a plan view. A first thickness of the first portion and a second thickness of the second portion are different from each other.

In an embodiment of the disclosure, a display device may include a circuit layer including a buffer layer on a base layer and a pixel transistor on the buffer layer, and a display layer disposed on the circuit layer and including a light-emitting element connected to the pixel transistor. The buffer layer may include a first layer on the base layer, a second layer on the first layer, and a third layer on the second layer. A thickness of the first layer may be greater than a thickness of the third layer in an area overlapping a semiconductor pattern of the pixel transistor in a plan view.

In an embodiment of the disclosure, a manufacturing method of a display device may include providing a conductive layer on a base layer, providing a preliminary lower layer on the base layer and the conductive layer, first-etching the preliminary lower layer in a first area overlapping the conductive layer in a plan view to form a lower layer, providing an intermediate layer on the lower layer, providing a preliminary upper layer on the intermediate layer, second-etching the preliminary upper layer in a second area non-overlapping the conductive layer in a plan view to form an upper layer, and providing, on the upper layer, a first semiconductor pattern overlapping the first area and a second semiconductor pattern overlapping the second area in a plan view.

In an embodiment of the disclosure, the method may further include forming a first groove overlapping the first area in the preliminary lower layer. A depth of the first groove may be in a range of about 200Å to about 300Å.

In an embodiment of the disclosure, a second groove corresponding to the first groove may be defined in the preliminary upper layer, and the second groove may be removed by the second-etching.

In an embodiment of the disclosure, the upper layer may include a first portion overlapping the first semiconductor pattern in a plan view, and a second portion overlapping the second semiconductor pattern in a plan view. A thickness of the second portion may be in a range of about 200Å to about 500Å after the second-etching.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIGS. 2A and 2B are exploded perspective views of a display device according to an embodiment of the disclosure;

FIG. 3 is a schematic cross-sectional view of a display module according to an embodiment of the disclosure;

FIG. 4 is a plan view of a partial configuration of a display module according to an embodiment of the disclosure;

FIG. 5 is a schematic block diagram of a display device according to an embodiment of the disclosure;

FIG. 6A is a schematic diagram of an equivalent circuit of a pixel according to an embodiment of the disclosure;

FIG. 6B is a schematic waveform diagram of driving signals for driving the pixel shown in FIG. 6A;

FIG. 7A is a schematic block diagram of first and second gate driving circuits according to an embodiment of the disclosure;

FIG. 7B is a schematic block diagram of a first write scan driving circuit according to an embodiment of the disclosure;

FIG. 7C is a schematic diagram of an equivalent circuit of a first stage according to an embodiment of the disclosure;

FIG. 8 is a schematic cross-sectional view of a display panel according to an embodiment of the disclosure;

FIG. 9 is an enlarged view of area AA′ representing a portion of the display panel of FIG. 8;

FIG. 10A is a graph showing the relationship between the thickness of a third layer and threshold voltages of transistors shown in FIG. 9;

FIG. 10B is a graph showing the relationship between the thickness of a third layer and a change amount of a threshold voltage of a first transistor shown in FIG. 9;

FIG. 11 is a schematic cross-sectional view of a display panel according to another embodiment of the disclosure; and

FIGS. 12A to 12G are schematic diagrams showing manufacturing processes of a portion of a display device shown in FIG. 9.

FIG. 13 is a perspective view of an electronic device according to an embodiment of the disclosure.

FIG. 14 is a view illustrating a folded state of the electronic device illustrated in FIG. 13.

FIG. 15 is an exploded perspective view of the electronic device illustrated in FIG. 13.

FIG. 16 is a schematic block diagram of the electronic device illustrated in FIG. 13.

FIG. 17 is a block diagram of an electronic device according to an embodiment.

FIG. 18 illustrates schematic views of electronic devices according to various embodiments.

### DETAILED DESCRIPTION OF THE EMBODIMENTS

The disclosure may be variously modified and realized in various forms, and thus embodiments will be illustrated in the drawings and described in detail hereinafter. However, it will be understood that the disclosure is not intended to be limited to the specific forms set forth herein, and all changes, equivalents, and substitutions included in the technical scope and spirit of the disclosure are included.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

In the specification and the claims, the phrase “at least one of” is intended to include the meaning of “at least one selected from the group of” for the purpose of its meaning and interpretation. For example, “at least one of A and B” may be understood to mean “A, B, or A and B. ” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or. ”

Terms such as first, second and the like may be used to describe various components, but these components should not be limited by the terms. Such terms are only used for distinguishing one element from other elements. For instance, a first component may be referred to as a second component, or similarly, a second component may be referred to as a first component, without departing from the scope of the disclosure. The singular expressions include plural expressions unless the context clearly dictates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

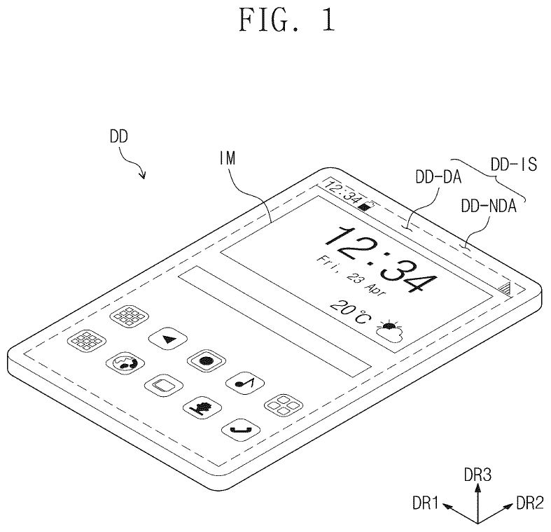

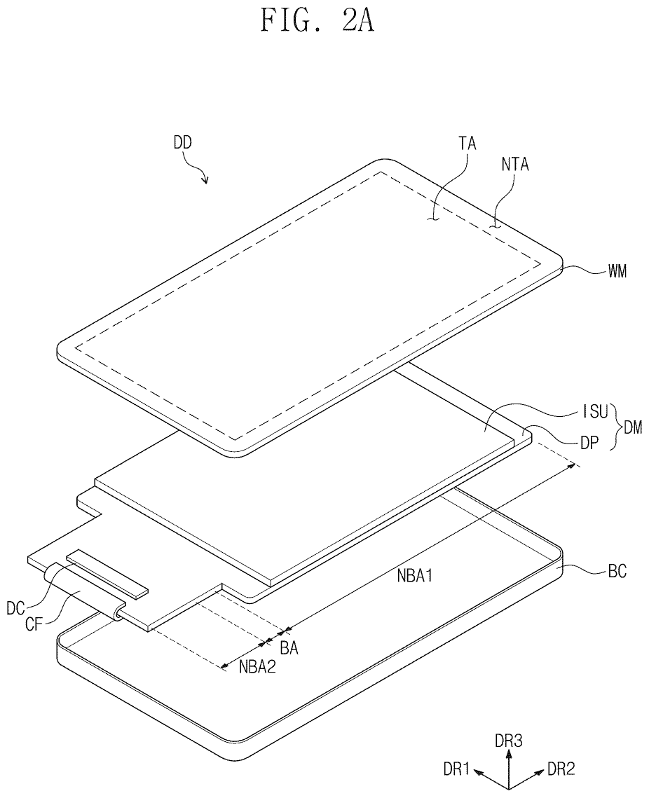

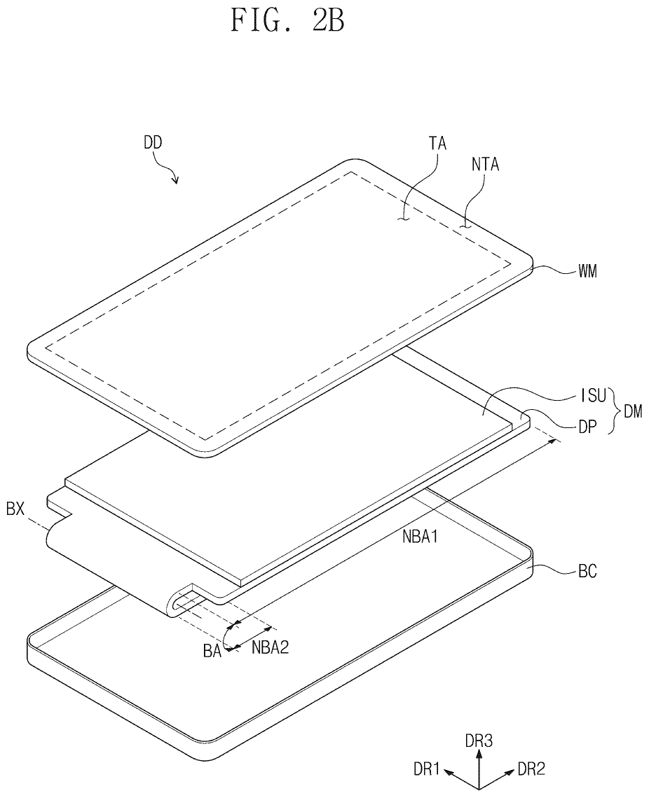

FIG. 1 is a perspective view of a display device according to an embodiment of the disclosure. FIGS. 2A and 2B are exploded perspective views of a display device according to an embodiment of the disclosure. FIG. 2B shows a state in which a display panel DP in the display device DD is bent. In the specification, a mobile phone is shown as an embodiment of the display device DD. The display device DD according to the disclosure may be applied to a small or medium electronic device such as a tablet, a vehicle navigator, a gaming device, a smart watch, or the like as well as a large electronic device such as a television, a monitor or the like.

Referring to FIG. 1, the display device DD may display an image IM through a display surface DD-IS. As an example of the image IM, icon images are shown. The display surface DD-IS may be parallel to a surface defined by a first direction DR1 and a second direction DR2. A normal direction of the display surface DD-IS, for example, a thickness direction of the display device DD may be a third direction DR3.

The display surface DD-IS may include a display area DD-DA on which the image IM is displayed and a non-display area DD-NDA adjacent to the display area DD-DA. The non-display area DD-NDA may be an area on which the image is not displayed. However, the disclosure is not limited thereto, and the non-display area DD-NDA may be disposed adjacent to a side of the display area DD-DA or may be omitted.

In the specification, the expression of “when viewed on a plane” or “in a plan view” may mean when viewed from the third direction DR3. The front surfaces (or top surfaces) and the rear surfaces (or bottom surfaces) of respective layers or units, which will be described hereinafter, may be divided by the third direction DR3. However, a combination of the first to third directions DR1, DR2 and DR3 may be changed to another combination.

Referring to FIGS. 2A and 2B, the display device DD may include a window WM, a display module DM, and a housing member BC.

The window WM may be disposed over the display module DM and may transmit an image provided from the display module DM to the outside. The window WM may include a transmission area TA and a non-transmission area NTA. The transmission area TA may overlap the display area DD-DA shown in FIG. 1 in a thickness direction of the display device DD and may have the shape corresponding to the display area DD-DA. The window WM may include a base layer and functional layers disposed on the base layer. The functional layers may include a protection layer, an anti-fingerprint layer or the like. The base layer of the window WM may be composed of glass, sapphire, a plastic, or the like. The base layer of the window WM may include an optically transparent insulation material. For example, the base layer of the window WM may include glass or a plastic. The base layer of the window WM may have a single-layer or multilayer structure. For example, the base layer of the window WM may include multiple plastic films bonded with an adhesive, or a glass substrate and a plastic film bonded with an adhesive.

The non-transmission area NTA may overlap the non-display area DD-NDA in the thickness direction and may have the shape corresponding to the non-display area DD-NDA. The non-transmission area NTA may have a relatively low optical transmittance in comparison to the transmission area TA. The non-transmission area NTA may be defined by a bezel pattern disposed in a portion of the base layer of the window WM, and an area in which the bezel pattern is not disposed may be defined as the transmission area TA. However, the technical spirit of the disclosure is not limited thereto, and in another embodiment, the non-transmission area NTA may be omitted.

Although not shown, an anti-reflection layer may be included in the window WM and the display module DM. The anti-reflection layer may reduce a reflection ratio of external light incident from the outside of the display device DD. The anti-reflection layer may include color filters. The color filters may have a prescribed array. For example, the color filters may be arranged in consideration of emission colors of the pixels included in the display panel DP to be described below. Furthermore, the anti-reflection layer may further include a black matrix adjacent to the color filters.

According to an embodiment of the disclosure, the display module DM may include the display panel DP and an input sensor ISU.

The display panel DP may be one of a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel. However, the disclosure is not limited thereto. Hereinafter, the display panel DP will be described as an organic light-emitting display panel.

The input sensor ISU may include one of a capacitive sensor, an optical sensor, an ultrasonic sensor, and an electromagnetic inductive sensor. The input sensor ISU may be provided on the display panel DP through continuous processes, or individually manufactured and adhered to the top side of the display panel DP via an adhesive layer, but the disclosure is not limited thereto.

The display module DM may include a printed circuit board CF and a driving chip DC. Although not shown, a main circuit board may be disposed on a side of the printed circuit board CF. The printed circuit board CF may electrically connect the display panel DP with the main circuit board. FIG. 2A shows an embodiment in which the driving chip DC is mounted on the display panel DP, but the disclosure is not limited thereto. The driving chip DC may generate a driving signal required to operate the display panel DP on the basis of a control signal transferred from the printed circuit board CF.

The display panel DP may include a bending area BA and first and second non-bending areas NBA1 and NBA2 spaced apart from each other in the second direction DR2 with the bending area BA interposed between the first and second non-bending areas NBA1 and NBA2.

The bending area BA may be an area in which the display panel DP is bendable along a virtual bending axis BX extending in the first direction DR1. The first non-bending area NBA1 may overlap the transmission area TA in the thickness direction, and the second non-bending area NBA2 may be connected with the printed circuit board CF. In case that the bending area BA of the display panel DP is bent about the bending axis BX, the printed circuit board CF and the driving chip DC may be disposed under the rear surface of the display panel DP. Although not shown, additional components may be disposed to compensate for a step generated by the bending area BA between the printed circuit board CF and the rear surface of the display panel DP.

According to an embodiment, the width of the first non-bending area NBA1 may be greater than the widths of the bending area BA and the second bending area NBA2 in the second direction DR2. However, the disclosure is not limited thereto, and the width of the bending area BA in the second direction DR2 may be provided to become narrow toward the second non-bending area NBA2 from the first bending area NBA1.

As shown in FIG. 2B, in case that a portion of the display panel DP is bent, the printed circuit board CF electrically bonded to the display panel DP may be disposed on the rear surface of the display panel DP.

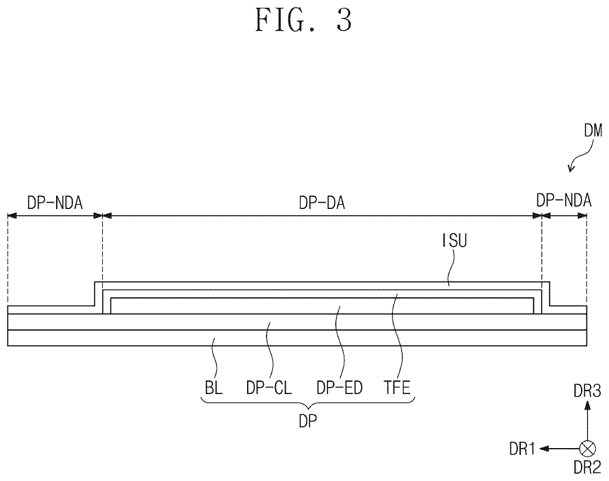

The housing member BC may house the display module DM and combine with the window WM. The printed circuit board CF may be disposed on an end of the display panel DP and electrically connected to the circuit element layer DP-CL (see FIG. 3). Although not shown, the display device DD may further include a main board, electronic modules mounted on the main board, a camera module, a power supply module or the like.

The display device DD has been described as a mobile phone, but the disclosure is not limited thereto, and the display device DD may include two or more electrically bonded electronic components. The display panel DP and the driving chip DC mounted on the display panel DP may respectively correspond to different electronic components, and these may configure the display device DD. However, the disclosure is not limited thereto.

In an embodiment, the display panel DP and the printed circuit board CF connected to the display panel DP may configure the display device DD, or the main board and the electronic module mounted on the main board may configure the display device DD. Hereinafter, the display device DD will be described focusing on a bonding structure of the display panel DP and the driving chip DC mounted on the display panel DP.

FIG. 3 is a schematic cross-sectional view of a display module according to an embodiment of the disclosure.

Referring to FIG. 3, the display panel DP may include a base layer BL, a circuit layer DP-CL disposed on the base layer BL, a display layer DP-ED, and an encapsulation layer TFE. The input sensor ISU may be disposed on the encapsulation layer TFE.

The display panel DP may include a display area DP-DA and a non-display area DP-NDA. The display area DP-DA of the display panel DP may correspond to the display area DD-DA shown in FIG. 1 or the transmission area TA shown in FIG. 2A, and the non-display area DP-NDA may correspond to the non-display area DD-NDA shown in FIG. 1 or the non-transmission area NTA shown in FIG. 2A. The non-display area DP-NDA may be referred to as a bezel area.

The base layer BL may include at least one plastic film. The base layer BL may be a flexible substrate and may include a plastic substrate, a glass substrate, a metal substrate, or an organic/inorganic composite material substrate, etc.

The circuit layer DP-CL may include at least one intermediate insulation layer and circuit elements. The intermediate insulation layer may include at least one intermediate inorganic layer and at least one intermediate organic layer. The circuit elements may include signal lines, a pixel driving circuit, etc.

The display layer DP-ED may include multiple organic light-emitting diodes. The display layer DP-ED may further include an organic layer such as a pixel definition layer.

The encapsulation layer TFE may encapsulate the display layer DP-ED. The encapsulation layer TFE may be disposed on the display layer DP-ED. The encapsulation layer TFE may overlap the display area DP-DA and the non-display area DP-NDA in the thickness direction. The encapsulation layer TFE may overlap at least a portion of the non-display area DP-NDA in the thickness direction. For example, the encapsulation layer TFE may include a thin-film encapsulation layer. The thin-film encapsulation layer may have a laminate structure of an organic layer/an inorganic layer/an organic layer. The encapsulation layer TFE may protect the display layer DP-ED from foreign matters such as moisture, oxygen and dust particles. However, the disclosure is not limited thereto, and the encapsulation layer TFE may further include additional insulation layers other than the thin-film encapsulation layer. For example, an optical insulation layer for controlling a refractive index may be further included.

In an embodiment of the disclosure, an encapsulation substrate may be provided instead of the encapsulation layer TFE. The encapsulation substrate may face the base layer BL, and the circuit layer DP-CL and the display layer DP-ED may be arranged between the encapsulation substrate and the base layer BL.

The input sensor ISU may be disposed on (e.g., directly disposed on) the display panel DP. In the specification, the expression “component A is directly disposed on component B” means that a separate layer is not disposed between component A and component B. In an embodiment, the input sensor ISU and the display panel DP may be manufactured through a continuous process. However, the disclosure is not limited thereto, and the input sensor ISU may be provided as an individual panel and coupled to the display panel DP via an adhesive layer. In another embodiment, the input sensor ISU may be omitted.

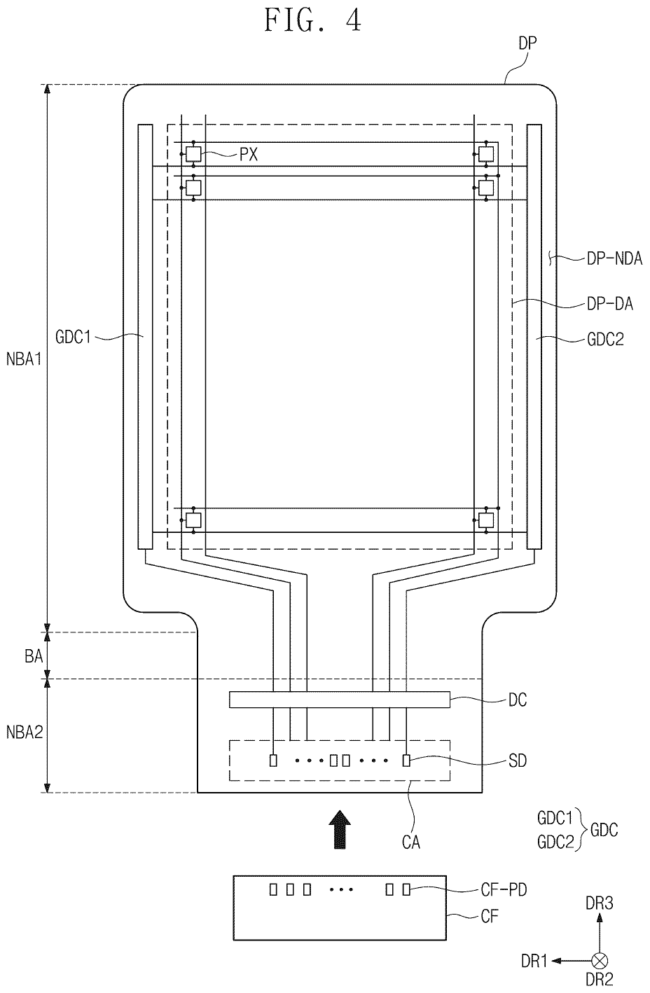

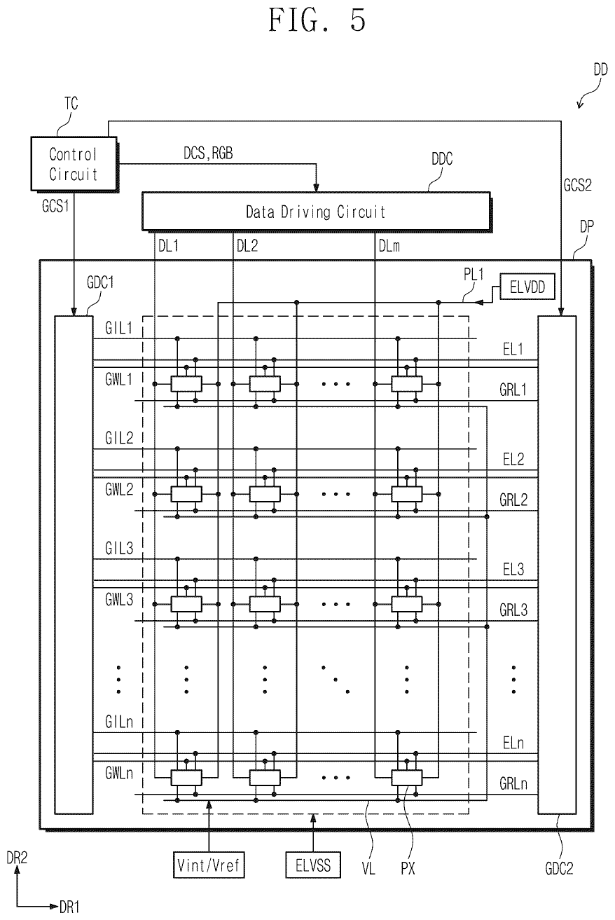

FIG. 4 is a plan view of a partial configuration of a display module according to an embodiment of the disclosure. FIG. 5 is a schematic block diagram of a display device according to an embodiment of the disclosure.

Referring to FIG. 4, the display panel DP may include multiple pixels PX, a gate driving circuit GDC, and multiple display pads SD. The pixels PX may be disposed in the display area DP-DA. Each of the pixels PX may include an inorganic light-emitting diode and a pixel driving circuit connected to the inorganic light-emitting diode. The gate driving circuit GDC may be included in the circuit layer DP-CL shown in FIG. 3.

The gate driving circuit GDC for driving the pixels PX may be disposed in the non-display area DP-NDA. For example, the gate driving circuit GDC may include a first gate driving circuit GDC1 disposed in the non-display area DP-NDA adjacent to a first side (e.g., the left side) of the display area DP-DA and a second gate driving circuit GDC2 disposed in the non-display area DP-NDA adjacent to a second side (e.g., the right side) of the display area DP-DA. The first and second driving circuits GDC1 and GDC2 may successively output gate signals to multiple gate lines GL. The first and second gate driving circuits GDC1 and GDC2 may include multiple thin-film transistors formed through a same process as a driving circuit of the pixels PX, for example, a low temperature polycrystalline silicon (LTPS) process or a low temperature polycrystalline oxide (LTPO) process. The display panel DP may further include another driving circuit configured to provide an emission control signal.

The display panel DP may include multiple display pads SD. The display pads SD may be spaced apart from each other by a distance. The display pads SD according to an embodiment may be disposed in the second non-bending area NBA2. The display pads SD may be disposed in a connection area CA in the second non-bending area NBA2. The connection area CA in the second non-bending area NBA2 may be an area in which the display pads SD are disposed and be defined as an area to which the printed circuit board CF is adhered.

The display pads SD may be disposed in the connection area CA. The driving chip DC may be mounted in the second non-bending area NBA2. The display pads SD may be electrically connected to the driving chip DC to transfer electrical signals received from the driving chip DC to the signal lines.

The printed circuit board CF may include board pads CF-PD electrically connected to the display panel DP. The board pads CF-PD may be arranged in the first direction DR1.

The display pads SD may be electrically connected to the board pads CF-PD included in the printed circuit board CF to transfer electrical signals received from the printed circuit board CF to the display panel DP. The printed circuit board CF may be rigid or flexible.

The printed circuit board CF may include a control circuit (see FIG. 5) configured to control the operation of the display panel DP. Although not shown, the control circuit TC may be mounted on the printed circuit board CF in an integrated chip. Furthermore, although not shown, the printed circuit board CF may include an input detection circuit configured to control the input sensor ISU (see FIG. 2A).

Referring to FIGS. 4 and 5, the display device DD may include the display panel DP, the first and second gate driving circuits GDC1 and GDC2, a data driving circuit DDC, and the control circuit TC.

The control circuit TC may drive the first and second gate driving circuits GDC1 and GDC2, and the data driving circuit DDC. The control circuit TC may convert the data format of input image signals so as to meet the specification of an interface with the data driving circuit DDC to generate image data RGB. The control unit TC may output the image data RGB and various types of control signals DCS, GCS1 and GCS2.

The first gate driving circuit GDC1 may receive the first gate control signal GCS1 from the control circuit TC, and the second gate driving circuit GCS2 may receive the second gate control signal GCS2 from the control circuit TC. The first gate control signal GCS1 may include a start signal for starting the operation of the first gate driving circuit GDC1, a clock signal for determining an output time of the signals, or the like, and the second gate control signal GCS2 may include a start signal for starting the operation of the second gate driving circuit GDC2, a clock signal for determining an output time of the signals, or the like. The first and second gate driving circuits GDC1 and GDC2 may output multiple scan signals to multiple scan lines GWL1 to GWLn, GRL1 to GRLn, and GIL1 to GILn described below. The first group scan lines GWL1 to GWLn among the scan lines GWL1 to GWLn, GRL1 to GRLn, and GIL1 to GILn may be referred to as write scan lines. The second group scan lines GRL1 to GRLn among the scan lines GWL1 to GWLn, GRL1 to GRLn, and GIL1 to GILn may be referred to as reference scan lines. The third group scan lines GIL1 to GILn among the scan lines GWL1 to GWLn, GRL1 to GRLn, and GIL1 to GILn may be referred to as initialization scan lines.

At least one of the first and second gate driving circuits GDC1 and GDC2 may generate multiple emission control signals and output the emission control signals to the emission signal lines EL1 to ELn.

The data driving circuit DDC may receive the data control signal DCS and the image data RGB from the control circuit TC. The data driving circuit DDC may convert the image data RGB into data signals, and output the data signals to multiple data lines DL1 to DLm described below. The data signals may have analog voltages corresponding to gradation values of the image data RGB. The data driving circuit DDC may be included in the driving chip DC shown in FIG. 2A.

The display panel DP may include the scan lines GWL1 to GWLn, GRL1 to GRLn, and GIL1 to GILn, the emission signal lines EL1 to ELn, the data lines DL1 to DLm, and the pixels PX. The scan lines GWL1 to GWLn, GRL1 to GRLn, and GIL1 to GILn may extend in the first direction DR1 and arranged in the second direction DR2 intersecting the first direction DR1. Each of the emission signal lines EL1 to ELn may be respectively arranged in parallel to the corresponding scan lines among the scan lines GWL1 to GWLn, GRL1 to GRLn, and GIL1 to GILn. The data lines DL1 to DLm may be insulated from and intersect with the scan lines GWL1 to GWLn, GRL1 to GRLn, and GIL1 to GILn.

Each of the pixels PX may be connected to a corresponding scan line among the gate lines GWL1 to GWLn, GRL1 to GRLn, and GIL1 to GILn, a corresponding emission line among the emission lines EL1 to ELn, and a corresponding data line among the data lines DL1 to DLm.

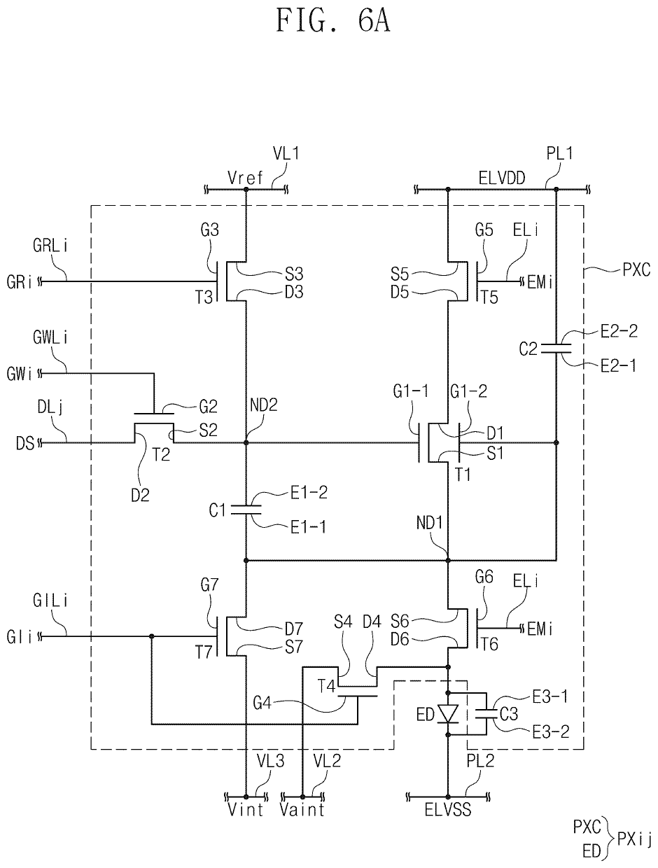

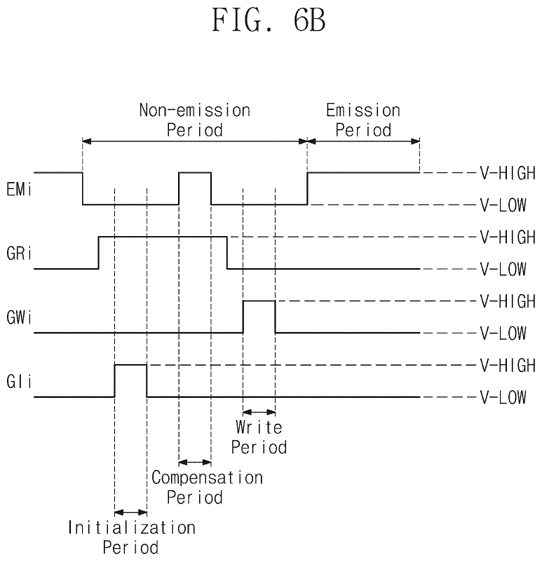

The display panel DP may receive a first power supply voltage ELVDD and a second power supply voltage ELVSS. The first power supply voltage ELVDD may be provided to the pixels PX through a first power line PL1. The second power supply voltage ELVSS may be provided to the pixels PX through a second power line PL2 (see FIG. 6A).

The display panel DP may further receive the initialization voltage Vint and a reference voltage Vref. The initialization voltage Vint and the reference voltage Vref may be provided to the pixels PX through the voltage lines VL.

FIG. 6A is a schematic diagram of an equivalent circuit of a pixel according to an embodiment of the disclosure. FIG. 6B is a schematic waveform diagram of driving signals for driving the pixel shown in FIG. 6A.

FIG. 6A schematically illustrates a pixel PXij connected to an i-th write scan line GWLi among the write scan lines GWL1 to GWLn (see FIG. 5) and to a j-th data line DLj among the data lines DL1 to DLm (see FIG. 5) according to an embodiment. The pixel PXij may be connected to an i-th reference scan line GRLi among the reference scan lines GRL1 to GRLn (see FIG. 5) and to an i-th initialization scan line GILi among the initialization scan lines GIL1 to GILn (see FIG. 5).

The pixel PXij may include a pixel circuit (or a pixel driving circuit) PXC and a light-emitting element ED connected to the pixel circuit PXC. In an embodiment, the pixel circuit PXC may include seven transistors (hereinafter, first to seventh pixel transistors T1to T7), and three capacitors (hereinafter, a first capacitor C1, a second capacitor C2, and a third capacitor C3). In an embodiment, the first to seventh pixel transistors T1to T7 each may include an oxide semiconductor. The first to seventh pixel transistors T1to T7 may be first type (e.g., N type) transistors. In an embodiment of the disclosure, at least one of the first to seventh pixel transistors T1to T7 may be omitted from the pixel PXij, or an additional pixel transistor may be further included in the pixel PXij.

In FIG. 6A, the first pixel transistor T1 is shown as including two gates (e.g., an upper gate and a lower gate), but the disclosure is not limited thereto, and the first pixel transistor T1 may include only one gate. In an embodiment, the first pixel transistor T1 may be referred to as a driving transistor, and the second pixel transistor T2 may be referred to as a switching transistor. A node to which the first pixel transistor T1 and the sixth pixel transistor T6 are connected may be defined as a first node ND1, and a node to which the first pixel transistor T1and the second pixel transistor T2 may be defined as a second node ND2. In an embodiment, the sixth pixel transistor T6 may be omitted, and the first pixel transistor T1may be connected to the light-emitting element ED through the first node ND1.

The light-emitting element ED may include a first electrode electrically connected to a source S6 of the sixth pixel transistor T6, a second electrode connected to the second power line PL2 configured to receive the second power supply voltage ELVSS, and an emission layer disposed between the first electrode and the second electrode. Detailed description of the light-emitting element ED will be provided below.

The first pixel transistor T1may be electrically connected between the first power line PL1 configured to receive the first power supply voltage ELVDD and the first node ND1. The first pixel transistor T1 may include a source S1 (hereinafter, a first source) connected to the first node ND1, a drain D1 (hereinafter, a first drain), a semiconductor area, and an upper gate G1-1 (hereinafter, a first upper gate) electrically connected to the second node ND2. The first pixel transistor T1 may further include a lower gate G1-2 (hereinafter, a first lower gate) connected to the first node ND1.

The second pixel transistor T2 may be electrically connected between the j-th data line DLj and the second node ND2. The second pixel transistor T2 may include a source S2 (hereinafter, a second source) connected to the second node ND2, a drain D2 (hereinafter, a second drain) connected to the j-th data line DLj, a semiconductor area, and a second upper gate G2 connected to the i-th write scan line GWLi. Although not shown, the second pixel transistor T2 may further include a gate (or a second lower gate) electrically connected to the second upper gate G2.

The third pixel transistor T3 may be electrically connected between the second node ND2 and the first voltage line VL1 configured to receive the reference voltage Vref. The third pixel transistor T3 may include a drain D3 (hereinafter, a third drain) connected to the second node ND2, a source S3 (hereinafter, a third source) connected to the first voltage line VL1, a semiconductor area, and a gate G3 (or a third upper gate) connected to the i-th reference scan line GRLi. The third pixel transistor T3 may further include a gate (or a third lower gate) electrically connected to the third upper gate G3.

The fourth pixel transistor T4 may be electrically connected between the second voltage line VL2 configured to receive the first initialization voltage Vaint and the light-emitting element ED. The fourth pixel transistor T4 may include a drain D4 (hereinafter, a fourth drain) connected to the first electrode of the light-emitting element ED, a source S4 (hereinafter, a fourth source) connected to the second voltage line VL2, a semiconductor area, and a gate G4 connected to the i-th initialization scan line GILi.

The fifth pixel transistor T5 may be electrically connected between the first power line PL1 and the first drain D1. In an embodiment, the fifth pixel transistor T5 may include a source S5 (hereinafter a fifth source) connected to the first power line PL1, a drain D5 (hereinafter a fifth drain) connected to the first drain D1, a semiconductor area, and a gate G5 (or a fifth upper gate) connected to the i-th emission signal line ELi. The fifth pixel transistor T5 may further include a gate (or a fifth lower gate) electrically connected to the fifth upper gate G5.

The sixth pixel transistor T6 may be electrically connected between the first node ND1 and the light-emitting element ED. In an embodiment, the sixth pixel transistor T6 may include the source S6 (hereinafter, a sixth source) connected to the first node ND1, a drain D6 (hereinafter, a sixth drain) connected to the first electrode of the light-emitting element ED, a semiconductor area, and a gate G6 (or a sixth upper gate) connected to the i-th emission signal line ELi. The sixth pixel transistor T6 may further include a gate (or a sixth lower gate) electrically connected to the sixth upper gate G6. In an embodiment of the disclosure, the sixth pixel transistor T6 may be omitted, and the first pixel transistor T1 may be connected to the light-emitting element ED through the first node N1.

The seventh pixel transistor T7 may be electrically connected between the second node ND2 and the third voltage line VL3. In an embodiment, the third voltage line VL3 may receive an initialization voltage Vint. For example, the first initialization voltage Vaint and the initialization voltage Vint may have different voltage levels. The seventh pixel transistor T7 may include a drain D7 (hereinafter, a seventh drain) connected to the second node ND2, a source S7 (hereinafter, a seventh source) connected to the third voltage line VL3, a semiconductor area, and a gate G7 (or a seventh upper gate) connected to the i-th initialization scan line GILi. The seventh pixel transistor T7 may further include a gate (or a seventh lower gate) electrically connected to the seventh upper gate G7.

The first capacitor C1 may be electrically connected between the first node ND1 and the second node ND2. The first capacitor C1 may include a first electrode E1-1 connected to the first node ND1, and a second electrode E1-2 connected to the second node ND2.

The second capacitor C2 may be electrically connected between the first power line PL1 and the first node ND1. The second capacitor C2 may include a first electrode E2-1 connected to the first node ND1, and a second electrode E2-2 connected to the power line PL1.

The third capacitor C3 may be electrically connected between the first and second electrodes of the light-emitting element ED. The third capacitor C3 may include a first electrode E3-1 connected to the first electrode of the light-emitting element ED, and a second electrode E3-2 connected to the second electrode of the light-emitting element ED.

The operation of the pixel PXij will be described more specifically with reference to FIGS. 6A and 6B. The display device DD (see FIG. 1) may display an image for each frame period. Each of the write scan lines, the reference scan lines, the initialization scan lines, and the emission signal lines may receive scan signals or emission control signals during the frame period. FIG. 6B shows a portion of the frame period.

Referring to FIGS. 6A and 6B, each of the scan signals EMi, GRi, GWi, and GIi may have a high voltage V-HIGH (or a high level) during a portion of the period, and have a low voltage V-LOW (or a low level) during another portion of the period. The aforementioned first to sixth N-type transistors T1 to T6 may be turned on in case that the corresponding scan signals have the high voltage V-HIGH.

During an initialization period, the third pixel transistor T3 and the fourth pixel transistor T4 may be turned on. During an initialization period, the second node ND2 may be initialized to the reference voltage Vref, and the first electrode of the light-emitting element ED may be initialized to the initialization voltage Vint via the turned-on fourth pixel transistor T4. The first capacitor C1 may be initialized with a difference value between the reference voltage Vref and the initialization voltage Vint. The second capacitor C2 may be initialized by a difference value between the first power supply voltage ELVDD and the initialization voltage Vint. The third capacitor C3 may be initialized by a difference value between the second power supply voltage ELVSS and the initialization voltage Vint.

During a compensation period, the third pixel transistor T3, the fifth pixel transistor T5, and the sixth pixel transistor T6 may be turned on. A threshold voltage of the first pixel transistor T1 may be compensated by coupling of the first capacitor C1.

During a write period, the second pixel transistor T2 may be turned on. The second pixel transistor T2 may output a voltage corresponding to a data signal DS. As a result, the first capacitor C1 may be charged with a voltage corresponding to the data signal DS. The first capacitor C1 may be charged by the data signal DS for which the threshold voltage of the first pixel transistor T1 is compensated. The threshold voltage of the first pixel transistor T1 may differ for each of the pixels PX (see FIG. 4), but the pixel PXij shown in FIG. 6A may provide a current having the amplitude proportional to the data signal DS to the light-emitting element ED regardless of a deviation of the threshold voltage of the first pixel transistor T1.

During an emission period, the fifth pixel transistor T5 and the sixth pixel transistor T6 may be turned on substantially simultaneously. A current output via the first pixel transistor T1 may be provided to the light-emitting element ED through the turned-on sixth pixel transistor T6. Therefore, the light-emitting element ED may emit light at a luminance corresponding to the current.

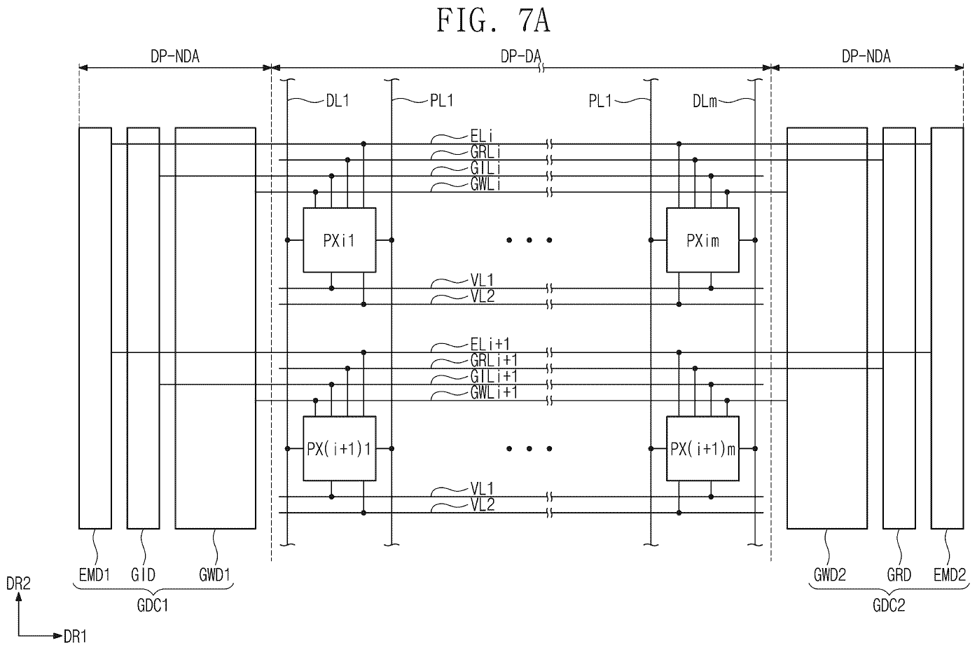

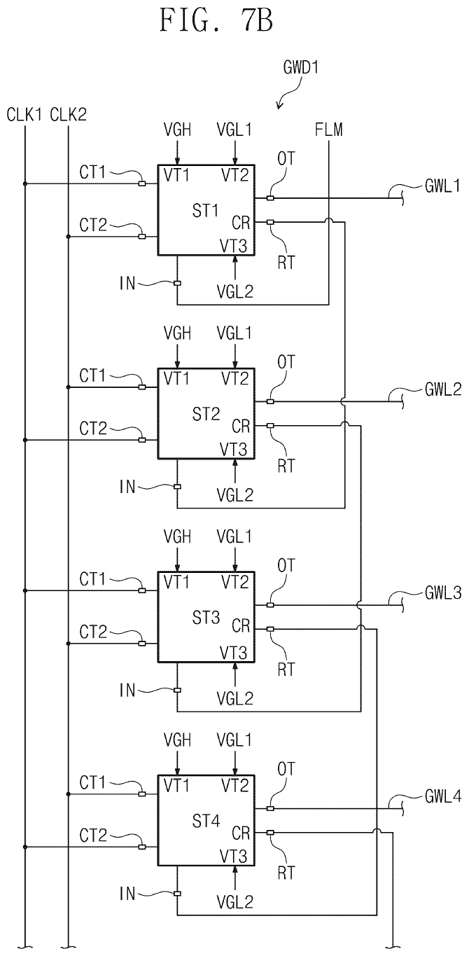

FIG. 7A is a schematic block diagram of the first and second gate driving circuits according to an embodiment of the disclosure. FIG. 7B is a schematic block diagram of the first write scan driving circuit according to an embodiment of the disclosure.

Referring to FIG. 7A, the first gate driving circuit GDC1 and the second gate driving circuit GDC2 may be disposed in the non-display area DP-NDA. The first gate driving circuit GDC1 may be disposed adjacent to a first side (e.g., the left side) and the second gate driving circuit GDC2 may be disposed adjacent to a second side (e.g., the right side) with respect to the display area DP-DA.

The first gate driving circuit GDC1 may include a first emission control circuit EMD1, a first scan driving circuit GWD1, and an initialization scan driving circuit GID. The second gate driving circuit GDC2 may include a second emission control circuit EMD2, a second write scan driving circuit GWD2, and a reference scan driving circuit GRD. In the first direction DR1 shown in FIG. 7A, the disposition sequence of the first emission control circuit EMD1, the first write scan driving circuit GWD1 and the initialization scan driving circuit GID, and the disposition sequence of the second emission control circuit EMD2, the second scan driving circuit GWD2 and the reference scan driving circuit GRD are merely illustrative and are not particularly limited.

The first and second emission control circuits EMD1 and EMD2 may be connected to the emission signal lines EL1 to ELn (see FIG. 5), and FIG. 7A only shows the i-th emission signal line ELi and the (i+1)-th emission signal line ELi+1 for simple illustration. The i-th write scan line GWLi and the (i+1)-th write scan line GWLi+1 shown in FIG. 7A are connected to the first and second write scan driving circuits GWD1 and GWD2. FIG. 7A also shows the i-th reference scan line GRLi and the (i+1)-th reference scan line GRLi+1 connected to the reference scan driving circuit GRD, and the i-th scan line GILi and the (i+1)-th scan line GILi+1 connected to the initialization scan driving circuit GID. Furthermore, FIG. 7A only shows pixels PXi1, PX(i+1)1, PXim, and PX(i+1)m connected to the first data line DL1 and the m-th data line DLm.

Referring to FIG. 7B, the first write scan driving circuit GWD1 is shown. The first write scan driving circuit GWD1 may include multiple stages ST1 to ST4 electrically connected to each other. The stages ST1 to ST4 may have the substantially same circuit configuration. FIG. 7B shows the four stages ST1 to ST4, but the first write scan driving circuit GWD1 may include stages respectively corresponding to the write scan lines GWL1 to GWLn shown in FIG. 5.

Each of the stages ST1 to ST4 may include an input terminal IN, a first control terminal CT1 , a second control terminal CT2, a carry terminal RT, and an output terminal OT. Each of the stages ST1 to ST4 may further include first to third voltage terminals VT1 to VT3.

The input terminal IN may receive a previous carry signal CR output from one carry terminal RT among previous stages, or a start signal FLM. The start signal FLM may be input to the input terminal of the first stage ST1. The input terminal IN of the second stage ST2 may receive a first write scan signal output from the output terminal OT of the first stage ST1.

Each of the stages ST1 to ST4 may receive the first and second clock signals CLK1 and CLK2 via the first and second control terminals CT1 and CT2. The first control terminal CT1 of each of the odd-numbered stages ST1 and ST3 among the stages ST1 to ST4 may receive the first clock signal CLK1, and the second control terminal CT2 of each of the odd-numbered stages ST1 and ST3 among the stages ST1 to ST4 may receive the second clock signal CLK2. On the contrary, the first control terminal CT1 of each of even-numbered stages ST2 and ST4 may receive the second clock signal CLK2, and the second clock terminal CT2 of each of even-numbered stages ST2 and ST4 may receive the first clock signal CLK1. The first clock signal CLK1 and the second clock signal CLK2 may have a same period but different phases. For example, the second clock signal CLK2 may have the inverted phase of the first clock signal CLK1.

The first voltage terminal VT1, the second voltage terminal VT2, and the third voltage terminal VT3 may be respectively provided with a high voltage VGH, a first low voltage VGL1, and a second low voltage VGL2. The high voltage VGH, the first low voltage VGL1 and the second low voltage VGL2 each may have a DC voltage level.

The high voltage VGH may be set to a high level of a scan signal, for example, to a gate-on voltage, and the first low voltage VGL1 may be set to a low level of the scan signal, example, a gate-off voltage. The second low voltage VGL2 may be a bias voltage having a different level from the first low voltage VGL1. The stages ST1 to ST4 may sequentially output write scan signals to the write scan lines GWL1 to GWL4.

FIG. 7C is a schematic diagram of an equivalent circuit of the first stage according to an embodiment of the disclosure. The circuit configuration of the first stage ST1 among the stages ST1 to ST4 will be described. Each of the stages ST1 to ST4 has a same circuit configuration, and thus the description of the circuit configuration of other stages ST2 to ST4 will be omitted.

Referring to FIG. 7C, the first stage ST1 may include an output unit OPC, a carry output unit COC, and a control unit CRC. The control circuit CRC may include first to fifth control transistors DT1 to DT5, and a control capacitor Cd. The carry output unit COC may include first to third carry transistors RT1 to RT3, and a carry capacitor Ce. The output unit OPC may include first to third buffer transistors BT1 to BT3.

In case that the second clock signal CLK2 has a low level, the first control transistor DT1 may be turned on. As the first control transistor DT1 is turned on, the potential of the first node NA may increase to a high level according to the voltage level of the start signal FLM. In case that the first clock signal CLK1 is a high level, the second control transistor DT2 may be turned on. As the second control transistor DT2 is turned on, the potential of the first node NA may increase to a high level according to the voltage level of the start signal FLM. In other words, in case that the first and second clock signals CLK1 and CLK2 have inverted phases to each other, the first and second control transistors DT1 and DT2 may be substantially simultaneously turned on, and the potential of the first control node NA may change to a high level in the turn-on period of the first and second control transistors DT1 and DT2. On the contrary, in case that the second clock signal CLK2 has a high level and the first clock signal has a low level, the first and second control transistors DT1 and DT2 may be substantially simultaneously turned off, and the potential of the first control node NA may change to a low level in the turn-off period of the first and second control transistors DT1 and DT2.

In case that the potential of the first control node NA has a high level, a third control transistor DT3 may be turned off, and the fourth control transistor DT4 may be turned on. Therefore, the first low voltage VGL1 may be applied to the second node NB via the turned-on fourth control transistor DT4. In case that the potential of the first control node NA has a low level, the third control transistor DT3 may be turned on, and the fourth control transistor CT4 may be turned off. Therefore, the high voltage VGH may be applied to the second node NB via the turned-on third control transistor DT3.

In case that the high voltage VGH is applied to the second control node NB, the first carry control transistor RT1 may be turned off, and the second carry transistor RT2 may be turned on. Therefore, the carry terminal RT may receive the first low voltage VGL1 via the turned-on second carry transistor RT2, and the first low voltage VGL1 may be output as the first write scan signal GWL1 (see FIG. 7B). In case that the first low voltage VGL1 is applied to the second control node NB, the second carry control transistor RT2 may be turned off, and the first carry transistor RT1 may be turned on. Therefore, the carry terminal RT may receive the high VGH via the turned-on first carry transistor RT1, and the high voltage VGL1 may be output as the first write scan signal GWL1.

In case that the high voltage VGH is applied to the second control node NB, the first buffer control transistor BT1 may be turned off, and the second buffer transistor BT2 may be turned on. Therefore, the output terminal OT may receive the first low voltage VGL1 via the turned-on second buffer transistor BT2, and the first low voltage VGL1 may be output as the first write scan signal GWL1. In case that the low voltage VGL1 is applied to the first control node NA, the second buffer control transistor BT2 may be turned off, and the first buffer transistor BT1 may be turned on. Therefore, the output terminal OT may receive the high VGH via the turned-on first buffer transistor BT1, and the high voltage VGH may be output as the first write scan signal GWL1.

The control capacitor Cd may be connected between the first control node NA and the first voltage terminal VT1 to maintain the potential of the first control node NA.

For example, the control unit CRC may further receive a power-on control signal ESR via a third control terminal CT3. The power-on control signal ESR may be activated during a power-on period in which the power begins to be supplied to the display device DD (see FIG. 3B). For example, the power-on control signal ESR may have a low level during the power-on period and a high level during a normal period after the power-on period. Therefore, the fifth control transistor DT5 may be turned on in response to the power-on control signal ESR of a low level. The high voltage VGH may be applied to the first control node NA via the fifth turned-on control transistor DT5 during the power-on period, and as a result, the second control node NB may be stably held to the first low voltage VGL1.

For example, the first stage ST1 may include two types of transistors. For example, the second buffer transistor BT2, the third carry transistor RT3, the second and fourth control transistors DT2 and DT4 may be first type transistors, and the first buffer transistor BT1, the first and second carry transistors RT1 and RT2, the first, third and fifth control transistors DT1, DT3 and DT5 may be second type transistors. The first type transistor may be an N-type transistor, and the second type transistor may be a P-type transistor. The second buffer transistor BT2, the third carry transistor RT3, the second and fourth control transistors DT2 and DT4 and the first to seventh pixel transistors T1 to T7 shown in FIG. 6A may be same type transistors, and the first buffer transistor BT1, the first and second carry transistors RT1 and RT2, the first, third and fifth control transistors DT1, DT3 and DT5 and the first to seventh pixel transistors T1 to T7 may be different type transistors.

In FIG. 7C, some transistors BT1,DT1,RT1, RT2, DT3, and DT5 among the transistors BT1, BT2, RT1 to RT3, and DT1 to DT5 included in the first stage ST1 may include silicon semiconductor (e.g., low temperature polycrystalline silicon (LTPS) semiconductors), and others BT2, RT3, DT2, and DT4 may include an oxide semiconductor. However, the disclosure is not limited thereto. Each of the transistors BT1, BT2, RT1 to RT3, and DT1 to DT5 included in the first stage ST1 may include an LTPS semiconductor.

In this way, as at least one of the transistors included in the gate driving circuit GDC includes a silicon semiconductor (e.g., an LTPS semiconductor), an increase in the area of the non-display area DP-NDA may be prevented.

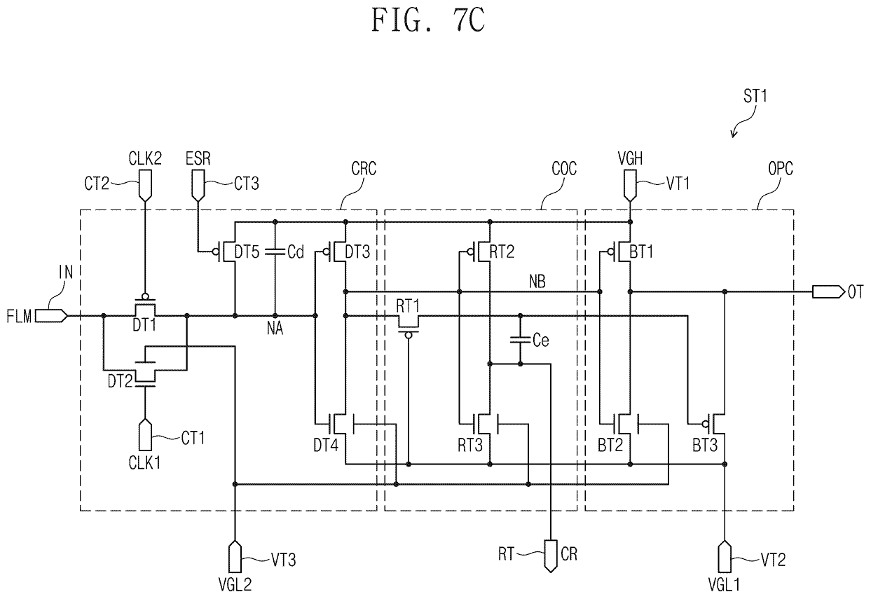

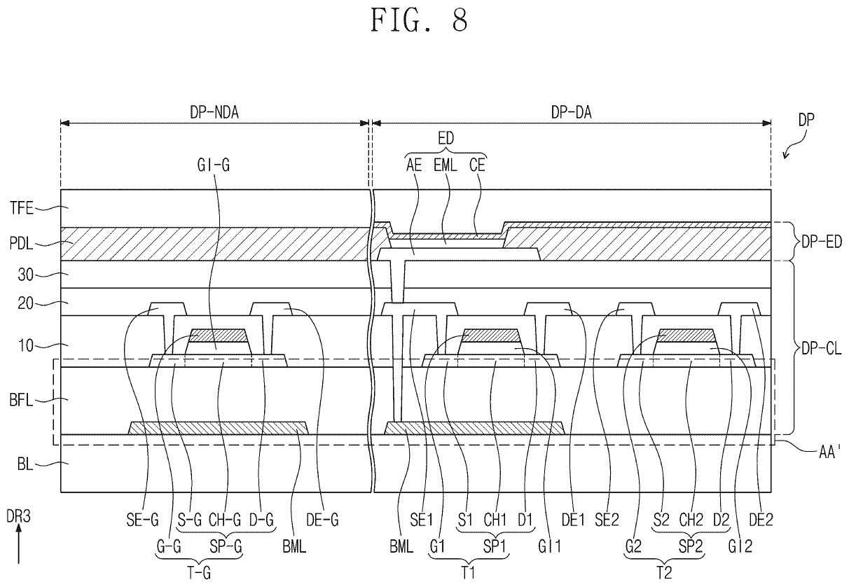

FIG. 8 is a schematic cross-sectional view of a display panel according to an embodiment of the disclosure. In FIG. 8, as a portion of the configuration of the display panel DP, a portion of the display area DP-DA and a portion of the non-display area DP-NDA are shown.

The display panel DP may include the base layer BL, a circuit layer DP-CL disposed on the base layer BL, and the display layer DP-ED disposed on the circuit layer DP-CL. The circuit layer DP-CL may include multiple transistors, and the display layer DP-ED may include the light-emitting element ED.

The base layer BL may provide a base surface with the circuit layer DP-CL disposed on the base layer BL. The base layer BL may include a glass substrate, a metal substrate, a polymer substrate, or an organic/inorganic composite material substrate.

In an embodiment, the base layer BL may include at least one synthetic resin layer. The synthetic resin layer included in the base layer BL may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, a polyimide-based resin, and a parylene-based resin.

In an embodiment, the base layer BL may be a flexible substrate. In case that the base layer BL is a flexible substrate, the base layer BL may be bendable, foldable, rollable or the like.

The circuit layer DP-CL may be disposed on the base layer BL. The circuit layer DP-CL may include multiple insulation layers, multiple semiconductor patterns, multiple conductive patterns, multiple electrodes, signal lines, or the like. The circuit layer DP-CL will be described in more detail below.

The display layer DP-ED may be disposed on the circuit layer DP-CL. The display layer DP-ED may include a pixel definition layer PDL and a light-emitting element ED. For example, the light-emitting element ED may include an organic light-emitting material, an inorganic-light emitting material, an organic-inorganic light-emitting material, quantum dots, quantum rods, micro LEDs, or nano-LEDs.

The light-emitting element ED may include a first electrode AE, a second electrode CE, and an emission layer EML. In an embodiment, the first electrode AE of the light-emitting element ED may be an anode, and the second electrode CE may be a cathode.

The first electrode AE of the light-emitting element ED and the pixel definition layer PDL may be disposed on the third insulation layer 30. The first electrode AE may be connected to a source electrode SE1 through a contact hole penetrating through at least the second and third insulation layers 20 and 30. As the first electrode AE is connected to the source electrode SE1, the first electrode AE may be electrically connected to each of the first source S1 of the first pixel transistor T1 and a shield layer BML. For example, the first electrode AE of the light-emitting element ED may be electrically connected to each of a semiconductor pattern SP1 and the shield layer BML of the first pixel transistor T1.

In the pixel definition layer PDL, an emission opening exposing at least a portion of the first electrode AE may be defined. In an embodiment, the portion of the first electrode AE exposed by the emission opening may correspond to an emission area.

The pixel definition layer PDL may include a polymer resin and further include an inorganic material included in the polymer resin. The pixel definition layer PDL in an embodiment may have a color. For example, the pixel definition layer PDL may include a base resin, and a black pigment and/or a black dye mixed in the base resin. However, the pixel definition layer PDL is not limited thereto.

The second electrode CE may face the first electrode AE. The second electrode CE may be commonly disposed over the pixels PX (see FIG. 4) disposed in the display area DP-DA. For example, the second electrode CE may be a common electrode provided in common to the pixels PX.

The emission layer EML may be disposed between the first electrode AE and the second electrode CE. The emission layer EML may include an organic material and/or inorganic material. The emission layer EML may be disposed as a pattern in an area corresponding to the emission opening defined in the pixel definition layer PDL. The emission layer EML may generate light of one of red, green, and blue colors. However, the disclosure is not limited thereto, and the emission layer EML may be disposed in common to the pixels and generate blue light or white light. FIG. 8 shows the light-emitting element ED including one emission layer EML, but the disclosure is not limited thereto. In another embodiment, the light-emitting element ED may be a tandem light-emitting element including multiple light-emitting stacks.

The light-emitting element ED may further include at least one functional layer provided between the first electrode AE and the emission layer EML, and the emission layer EML and the second electrode CE. The light-emitting element ED may further include, for example, a hole control layer provided between the first electrode AE and the emission layer EML, and an electron control layer provided between the second electrode CE and the emission layer EML. Each of the hole control layer and the electron control layer may be disposed in common in the pixels. The hole control layer may include at least one of a hole injection layer, a hole transport layer, and an electron blocking layer. The electron control layer may include at least one of an electron injection layer, an electron transport layer, and a hole blocking layer.

The encapsulation layer TFE may be disposed on the display layer DP-ED. The encapsulation layer TFE may protect the display layer DP-ED, for example, the light-emitting element from foreign matters such as moisture, oxygen and dust particles. The encapsulation layer TFE may include at least one encapsulation inorganic layer. The encapsulation layer TFE may include a laminate structure of a first inorganic encapsulation layer, an organic encapsulation layer, and a second inorganic encapsulation layer.

The insulation layers and insulation patterns, the semiconductor patterns, the conductive patterns, the electrodes, and the signal lines of the circuit layer DP-CL may be formed by providing the insulation layer, the semiconductor layer, the conductive layer or the like on the base layer BL by coating or deposition, and patterning the same through multiple photolithography processes. Deposition, photolithography, and etching processes may be sequentially repeated according to the laminate sequence of the patterns included in the circuit layer DP-CL.

The circuit layer DP-CL may include the pixel transistors constituting multiple pixel circuits PXC (see FIG. 6A) of the pixels PX (see FIG. 4) and the transistors constituting the gate driving circuits GDC1 and GDC2 (see FIG. 4).

The cross-sectional structures of the circuit layer DP-CL shown in FIG. 8 or the like are illustrative, and may be differed according to a manufacturing process, the configuration of the pixel circuit, the configuration of the gate driving circuit, or the like of the circuit layer DP-CL.

The circuit layer DP-CL may include a buffer layer BFL and first to third insulation layers 10, 20 and 30 as an insulation layer. The circuit layer DP-CL may further include the shield layer BML. Furthermore, the circuit layer DP-CL may include the pixel transistors T1 and T2, a transistor T-G, and electrode patterns SE1, SE2, DE1, DE2, SE-G and DE-G. The electrode patterns SE1, SE2, DE1, DE2, SE-G and DE-G may be electrically connected to the pixel transistors T1 and T2, the transistor T-G, or the shield layer BML.

The shield layer BML may be disposed on the base layer BL. The shield layer BML may be composed of a metal material. The shield layer BML may overlap the transistors or the like in the thickness direction to protect the semiconductor patterns of the transistors. For example, the shield layer BML may overlap the first transistor T1 and the transistor T-G in the thickness direction. The shield layer BML may be disposed under the first transistor T1 and the transistor T-G to block the influence of an electric potential to the first transistor T1 and the transistor T-G, or to protect each of the first transistor T1 and the transistor T-G from external light.

The shield layer BML in an embodiment may be connected to electrodes or wirings to receive a constant voltage. Furthermore, the shield layer BML in an embodiment may be a floating pattern isolated from another electrode or wiring.

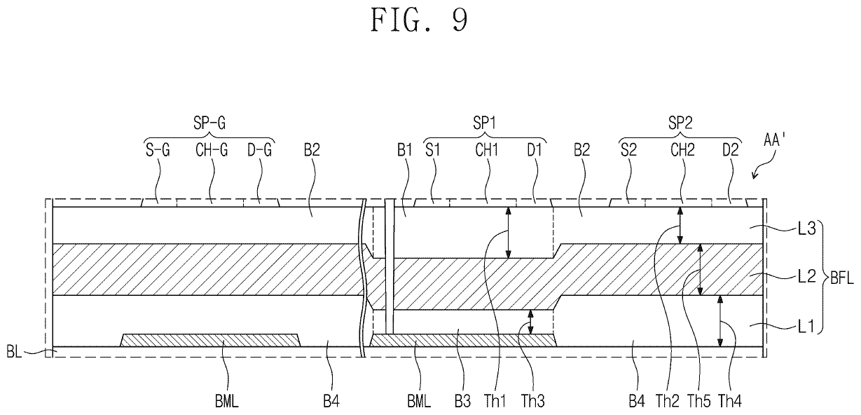

The buffer layer BFL may be disposed on the base layer BL. The buffer layer BFL may improve a bonding between the base layer BL and the semiconductor patterns SP1, SP2 and SP-G and/or the shield layer BML. The buffer layer BFL may cover the shield layer BML. The buffer layer BFL may include multiple layers. For example, the layers may include at least one of aluminum oxide, titanium oxide, silicon oxide, silicon nitride, silicon oxynitride, zirconium oxide and halfnium oxide. Detailed description thereof will be provided below with reference to FIG. 9.

The first to third insulation layers 10, 20 and 30 may be disposed on the buffer layer BFL. The first to third insulation layers 10, 20 and 30 may be sequentially laminated in the third direction DR3. However, the disclosure is not limited thereto, and the number and laminate structure of the insulation layers included in the circuit layer DP-CL is not limited thereto.

The first insulation layer 10 may be disposed on the buffer layer BFL. The first insulation layer 10 may be an inorganic layer. In the first insulation layer 10, contact holes may be defined which expose the sources S1, S2 and S-G and the drains D1, D2 and D-G or the like. Furthermore, contact holes in which connection electrodes or the like connected to the shield layer EML are disposed may be defined in the first insulation layer 10.

The second insulation layer 20 may be disposed on the first insulation layer 10. The second insulation layer 20 may be an inorganic layer. The second insulation layer 20 may cover the electrode patterns SE1, SE2, DE1, DE2, SE-G and DE-G disposed on the first insulation layer 10. The top surface of the second insulation layer 20 may be a flat surface.

The third insulation layer 30 may be disposed on the second insulation layer 20. The third insulation layer 30 may be an inorganic layer. The top surface of the third insulation layer 30 may be a flat surface. A contact hole may be defined in the third insulation layer 30, and the light-emitting element ED and the first pixel transistor T1 may be electrically connected through the contact hole in the third insulation layer 30.

The pixel transistors T1 and T2 and the transistor T-G may be covered by the second and third insulation layers 20 and 30. Each of the second and third insulation layers 20 and 30 may include silicon nitride. In an embodiment, each of the second and third insulation layers 20 and 30 may have a laminate structure in which multiple layers are laminated. In case that the second or third insulation layer 20 or 30 has a structure including multiple layers, at least one of the layers may be a planarization layer.

Besides, the buffer layer BFL or the insulation layers 10, 20 and 30 may also have a contact hole. The contact hole may be formed by penetrating through a portion of the laminated insulation layers or be defined in a partial area without penetrating the insulation layers. Through the contact hole, the shield layer BML and the electrodes may be connected, the semiconductor pattern and the electrode pattern or the wiring may be connected, the light-emitting element and the transistors may be connected, or the wiring and the conductive pattern and the like may be connected.

For example, the first electrode AE may be connected to the first source electrode SE1 connected to the first source S1 of the first pixel transistor T1 through a contact hole formed by penetrating through the second and third insulation layers 20 and 30. The first source electrode SE1 of the first pixel transistor T1 may be electrically connected to the source S1 through the contact hole defined in the first insulation layer 10, and also connected to the shield layer BML through the contact hole defined in the first insulation layer 10 and the buffer layer BFL.

The transistors T-G, T1 and T2 may be disposed on the buffer layer BFL. In an embodiment, the first pixel transistor T1 and the second pixel transistor T2 may be disposed in the display area DP-DA, and the transistor T-G may be disposed in the non-display area DP-NDA.

The oxide semiconductor may be referred to as a metal oxide semiconductor. The metal oxide semiconductor material may be a crystalline or amorphous oxide. For example, the semiconductor pattern may include an oxide of a metal such as zinc (Zn), indium (In), gallium (Ga), tin (Sn), titanium (Ti) or the like, or a mixture of a metal such as Zn, In, Ga, Sn, Ti or the like and an oxide thereof. In an embodiment, the semiconductor pattern may include, as an oxide semiconductor material, a transparent conductive oxide (TCO) such as indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), or the like.

The silicon oxide semiconductor may include multiple areas divided according to whether a metal oxide is reduced. A zone (hereinafter, a reduction zone) in which the metal oxide is reduced has a high conductivity in comparison to a zone (hereinafter, a non-reduction zone) in which the metal oxide is not reduced. The reduction zone may substantially serve as a source/drain or a signal line of the transistor. The non-reduction zone may substantially correspond to a channel area (or a semiconductor area, an active area) of the transistor. In other words, a portion of the second semiconductor pattern may be the channel area of the transistor, another portion may be a source/drain area of the transistor, and still another portion may be a signal transfer area.

The semiconductor pattern in the specification may be referred to as an active layer. Furthermore, the non-reduction zone may be referred to as the channel area, and the reduction zone may be referred to as the source area or the drain area according to an applied voltage.

The first pixel transistor T1 may include a first gate G1 and a first semiconductor pattern SP1 including a first source S1, a first channel portion CH1, and a first drain D1. The first source S1 and the first drain D1 of the first pixel transistor T1 may extend in opposite directions from the first channel portion CH1. A first gate insulation pattern GI1 may be disposed between the first semiconductor pattern SP1 and the first gate G1. The first gate G1 may be disposed on the first gate insulation pattern GI1 and spaced apart from the first semiconductor pattern SP1 in the third direction DR3. The first gate G1 may overlap the first channel portion CH1 in the thickness direction. For example, the width of the first channel portion CH1 may be determined to correspond to the first gate G1.

The first source S1 and the first drain D1 or the like of the first pixel transistor T1 may be connected to an electrode or a signal wiring through the contact hole or the like defined in the first insulation layer 10. The first source S1 may be connected to the first source electrode SE1, and the first drain D1 may be connected to the first drain electrode DE1. The first source electrode SE1 may be electrically connected to the shield layer BML through the contact hole defined in the buffer layer BFL and the first insulation layer 10. The first source electrode SE1 may be electrically connected to the light-emitting element ED via the first electrode AE. The first source electrode SE1 and the first drain electrode DE1 may be covered by the second insulation layer 20.

The second pixel transistor T2 may include a second gate G2 and a second semiconductor pattern SP2 including a second source S2, a second channel portion CH2, and a second drain D2. The first pixel transistor T1 and the second pixel transistor T2 shown in FIG. 8 may respectively correspond to the first pixel transistor T1 and the second transistor T2 shown in FIG. 6A. In other words, the first pixel transistor T1 may be a driving transistor, and the second pixel transistor T2 may be a switching transistor.

The second source S2 and the second drain D2 of the second pixel transistor T2 may extend in opposite directions from the second channel portion CH2. A second gate insulation pattern GI2 may be disposed between the second semiconductor pattern SP2 and the second gate G2. The second gate G2 may be disposed on the second gate insulation pattern GI2 and spaced apart from the second semiconductor pattern SP2 in the third direction DR3. The second gate G2 may overlap the second channel portion CH2 in the thickness direction. For example, the width of the second channel portion CH2 may be determined to correspond to the second gate G2.

The second source S2 and the second drain D2 or the like of the second pixel transistor T2 may be connected to an electrode or a signal wiring through the contact hole or the like defined in the first insulation layer 10. The second source S2 may be connected to the second source electrode SE2, and the second drain D2 may be connected to the second drain electrode DE2. The shield layer BML may not be disposed under the second pixel transistor T2. The second source electrode SE2 and the second drain electrode DE2 may be covered by the second insulation layer 20.

At least one of the first semiconductor pattern SP1 and the second semiconductor pattern SP2 may include an oxide semiconductor. In another embodiment, each of the first semiconductor pattern SP1 and the second semiconductor pattern SP2 may include an oxide semiconductor. As each of the first semiconductor pattern SP1 and the second semiconductor pattern SP2 includes an oxide semiconductor material, the electron mobility in the first and second pixel transistors T1 and T2 may increase, and current leakage may decrease.

In an embodiment, the first pixel transistor T1 and the second pixel transistor T2 may be disposed on a same layer. However, the disclosure is not limited thereto. In another embodiment, the first semiconductor pattern SP1 of the first pixel transistor T1 and the second semiconductor pattern SP2 of the second pixel transistor T2 may be disposed on different layers. In an embodiment, the first pixel transistor T1 and the second pixel transistor T2 may overlap each other in the third direction DR3. A conductive pattern may be further disposed between the first pixel transistor T1 and the second pixel transistor T2.

The display panel DP according to an embodiment of the disclosure may include multiple transistors disposed in the non-display area DP-NDA. FIG. 8 shows the one transistor T-G among the transistors.

In an embodiment, the transistor T-G may be disposed on the buffer layer BFL. The transistor T-G may include a third gate G-G and a third semiconductor pattern SP-G including a third source S-G, a third channel portion CH-G and a third drain D-G. The third source S-G and the third drain D-G of the transistor T-G may extend in opposite directions from the third channel portion CH-G. A third gate insulation pattern GI-G may be disposed between the third semiconductor pattern SP-G and the third gate G-G. The third gate G-G may be disposed on the third gate insulation pattern GI-G and spaced apart from the third semiconductor pattern SP-G in the third direction DR3. The third gate G-G may overlap the third channel portion CH-G in the thickness direction. For example, the width of the third channel portion CH-G may be determined to correspond to the third gate G-G.

The third source S-G and the third drain D-G or the like of the transistor T-G may be connected to an electrode or a signal wiring through the contact hole or the like defined in the first insulation layer 10. The third source S-G may be connected to the third source electrode SE-G, and the third drain D-G may be connected to the third drain electrode DE-G. Unlike the shown, the third source electrode SE-G may be electrically connected to the shield layer BML through the contact hole defined in the buffer layer BFL and the first insulation layer 10.

The transistor T-G shown in FIG. 8 may correspond to one of the second buffer transistor BT2, the third carry transistor RT3, and the second and fourth control transistors DT2 and DT4 shown in FIG. 7C. For example, the third semiconductor pattern SP-G of the transistor T-G may include an oxide semiconductor. As the third semiconductor pattern SP-G of the transistor T-G includes an oxide semiconductor material, the electron mobility may increase in the transistor T-G, and current leakage may decrease.

FIG. 9 is an enlarged view of area AA′ of a portion of the display panel of FIG. 8. The overlapping description with those described above will be omitted.

Referring to FIG. 9, the buffer layer BFL may include a first layer L1, a second layer L2, and a third layer L3 that are sequentially laminated. In an embodiment, the first layer L1 may be referred to as a lower layer, the second layer L2 may be referred to as an intermediate layer, and the third layer L3 may be referred to as an upper top layer. The first layer L1 may be disposed on the base layer BL and cover the shield layer BML. The third layer L3 may be disposed on the top of the buffer layer BFL and closest to the semiconductor patterns SP1, SP2 and SP-G. The second layer L2 may be disposed between the first layer L1 and the third layer L3. The first layer L1 and the third layer L3 may include a same material. For example, each of the first layer L1 and the third layer L3 may include silicon oxide (SiOₓ). The second layer L2 and the first layer L1 and the third layer L3 may include different materials. For example, the second layer L2 may include silicon nitride (SiNₓ).

The third layer L3 may include a first portion B1 and a second portion B2. The first portion B1 may overlap the first semiconductor pattern SP1 and the second portion B2 may not overlap the first semiconductor pattern SP1 in the thickness direction. In the disclosure, a section of the second portion B2, which overlaps the second semiconductor pattern SP2, may be referred to as a second section, and a section of the second portion B2, which overlaps the semiconductor pattern SP-G, may be referred to as a sub-section.

In an embodiment of the disclosure, a first thickness Th1 of the first portion B1 and a second thickness Th2 of the second portion B2 may be different from each other. The first thickness Th1 of the first portion B1 may be greater than the second thickness Th2 of the second portion B2. For example, the first thickness Th1 of the first portion B1 may be in a range of about 500 Å to about 800 Å, and the second thickness Th2 of the second portion B2 may be in a range of about 200 Å to about 500 Å. The difference between the first thickness Th1 of the first portion B1 and the second thickness Th2 of the second portion B2 may be in a range of about 200 Å to about 300 Å.

The first layer L1 may include a third portion B3 and a fourth portion B4. The third portion B3 may overlap the first semiconductor pattern SP1, and the fourth portion B4 may not overlap the first semiconductor pattern SP1 in the thickness direction. In the disclosure, a section of the fourth portion B4, which overlaps the second semiconductor pattern SP2, may be referred to as a third section, and a section of the fourth portion B4, which overlaps the semiconductor pattern SP-G may be referred to as a sub-section.

In an embodiment of the disclosure, a third thickness Th3 of the third portion B3 and a fourth thickness Th4 of the fourth portion B4 may be different from each other. The fourth thickness Th4 of the fourth portion B4 may be greater than the third thickness Th3 of the third portion B3. For example, the fourth thickness Th4 of the fourth portion B4 may be in a range of about 500 Å to about 800 Å, and the third thickness Th3 of the third portion B3 may be in a range of about 200 Å to about 500 Å. The difference between the fourth thickness Th4 of the fourth portion B4 and the third thickness Th3 of the third portion B3 may be in a range of about 200 Å to about 300 Å . For example, the first thickness Th1 of the first portion B1 and the fourth thickness Th4 of the fourth portion B4 may be the same, and the second thickness Th2 of the second portion B2 and the third thickness Th3 of the third portion B3 may be the same.

According to an embodiment of the disclosure, the thickness Th5 of the second layer L2 may be constant in a cross-sectional view. The thickness Th5 of the second layer L2 may be in a range of about 1800 Å to about 2200 Å. Furthermore, the sum of the first thickness Th1 of the first portion B1 and the third thickness Th3 of the third portion B3 and the sum of the second thickness Th2 of the second portion B2 and the fourth thickness Th4 of the fourth portion B4 may be the same. Accordingly, the sum of the thickness of the first layer L1 and the thickness of the third layer L3 may be constant. As a result, caps generated between the shield layer BML and the transistors T1 and T-G may be constant.

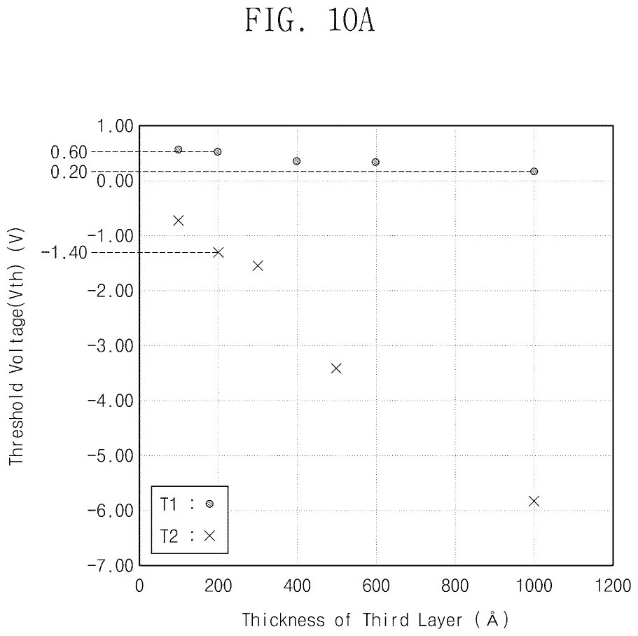

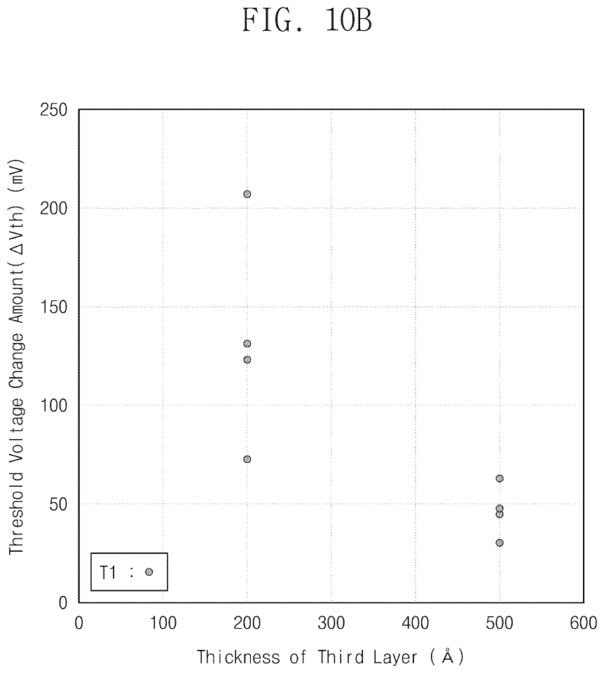

FIG. 10A is a graph showing the relationship between the thickness of the third layer shown in FIG. 9 and a threshold voltage of transistors. An x-axis corresponds to the thickness of the third layer L3 shown in FIG. 9, and a y-axis corresponds to the threshold voltage (Vth) of the transistors T1 and T2 shown in FIG. 8.

Referring to FIGS. 8 to 10A, it may be confirmed that the threshold voltage (Vth) of the first transistor T1 may be more negative as the third layer L2 becomes thicker. For example, as the third layer L3 becomes thicker, ranging from about 200 Å to about 1000 Å, the threshold voltage (Vth) of the first transistor T1 becomes lower, ranging from about 0.6 V to about 0.2 V.

Similarly, it also may be confirmed that the threshold voltage (Vth) of the second transistor T2 may become more negative as the third layer L3 becomes thicker. For example, as the third layer L3 becomes thicker, ranging from about 200 Å to about 1000 Å, the threshold voltage (Vth) of the first transistor T1 becomes lower, ranging from about −1.40 V to about −6.00 V.

The first transistor T1 may be a driving transistor, and thus a degradation amount may be reduced under a stress of voltage or temperature, as the threshold voltage (Vth) moves towards negative voltage. Furthermore, the second transistor T2 may be a switching transistor, and as the second transistor T2 includes the second semiconductor pattern SP2 (see FIG. 8), an oxygen concentration of the second semiconductor pattern SP2 may be adjusted. In other words, as the threshold voltage (Vth) becomes more positive, the threshold voltage (Vth) of a short channel length transistor may be effectively controlled. For example, as the threshold voltage (Vth) of the first transistor T1 moves towards more negative voltage, the reliability of the first transistor T1 may be secured, and as the threshold voltage (Vth) of the second transistor T2 moves towards more positive voltage, the reliability of the second transistor T2 may be secured

FIG. 10B is a graph showing the relationship between the thickness of the third layer shown in FIG. 9 and a change amount (ΔVth) of the threshold voltage of the first transistor. An x-axis corresponds to the thickness of the third layer L3 shown in FIG. 9, and a y-axis corresponds to the threshold voltage change amount (ΔVth) of the first transistor T1 shown in FIG. 8. A controllable threshold voltage change amount (ΔVth) with respect to an output current that can be output may correspond to the safety of the current. For example, as the threshold voltage change amount (ΔVth) increases, the stability of the output current decreases, and as the threshold voltage change amount (ΔVth) decreases, the stability of the output current increases.

Referring to FIGS. 8, 9 and 10B, it may be confirmed that the threshold voltage change amount (ΔVth) of the first transistor T1 may be more negative as the third layer L2 becomes thicker. For example, as the third layer L3 becomes thicker, ranging from about 200 Å to about 500 Å, the threshold voltage change amount (ΔVth) of the first transistor T1 becomes smaller. For example, as the third layer L3 is thicker, the stability of the output current becomes higher.

Referring to FIGS. 8 to 10B, the third layer L3 of the disclosure may include the first portion B1 overlapping the first semiconductor pattern SP1 and the second portion B2 overlapping the second semiconductor pattern SP2. The first thickness Th1 of the first portion B1 overlapping the first semiconductor pattern SP1 may be set thicker than the second thickness Th2 of the second portion B2 overlapping the second semiconductor pattern SP2. For example, the first thickness Th1 of the first portion B1 may be in a range of about 500 Å to about 800 Å, and the second thickness Th2 of the second portion B2 may be in a range of about 200 Å to about 500 Å. As a result, the threshold voltage (Vth) of the first transistor T1 moves towards more negative and the output current becomes more stable, and thus the reliable first transistor T1 may be provided. Furthermore, the threshold voltage (Vth) of the second transistor T2 moves towards more positive, and thus the reliable second transistor T2 may be provided.

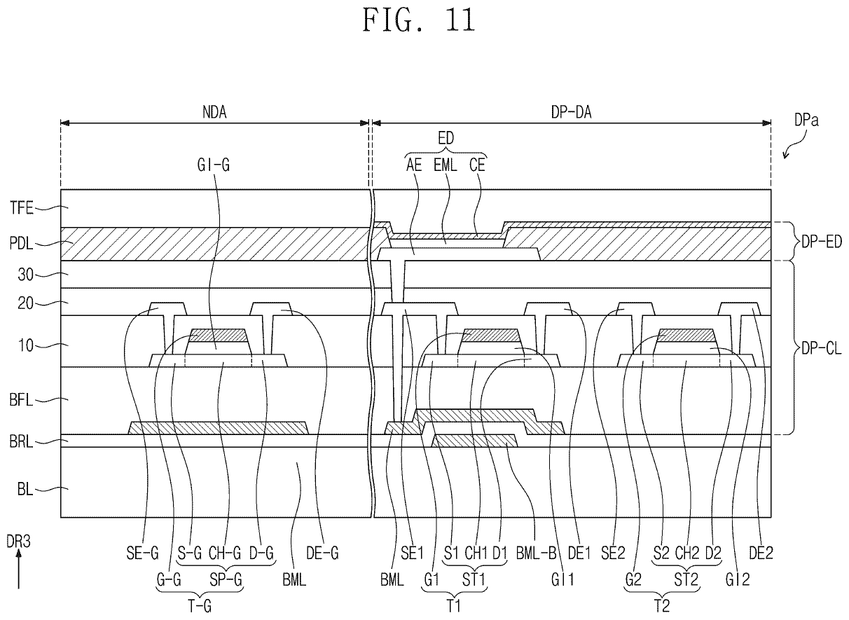

FIG. 11 is a schematic cross-sectional view of a display panel according to another embodiment of the disclosure. The overlapping description with those described above will be omitted.

Referring to FIG. 11, the display panel Dpa according to an embodiment of the disclosure may further include a lower conductive layer BML-B disposed on the base layer BL and a barrier layer BRL disposed on the base layer BL and the lower conductive layer BML-B.

The lower conductive layer BML-B may be composed of a metal material. For example, the lower conductive layer BML-B and the shield layer BML may include a same material. The lower conductive layer BML-B may serve as a light blocking pattern. The lower conductive layer BML-B may overlap the first transistor T1 in the thickness direction and block light incident towards the first semiconductor pattern SP1 of the first transistor from the outside. Accordingly, the lower conductive layer BML-B may prevent the external light from changing the voltage-current characteristics of the first transistor T1.

The barrier layer BRL may include multiple inorganic layers. The barrier layer BRL may prevent foreign matters from entering the semiconductor patterns SP1, SP2 and SP-G from the outside. The barrier layer BRL may include a silicon oxide layer and a silicon nitride layer. Each of the silicon oxide layer and the silicon nitride layer may be provided in plural, and the silicon oxide layers and the silicon nitride layers may be alternately laminated.

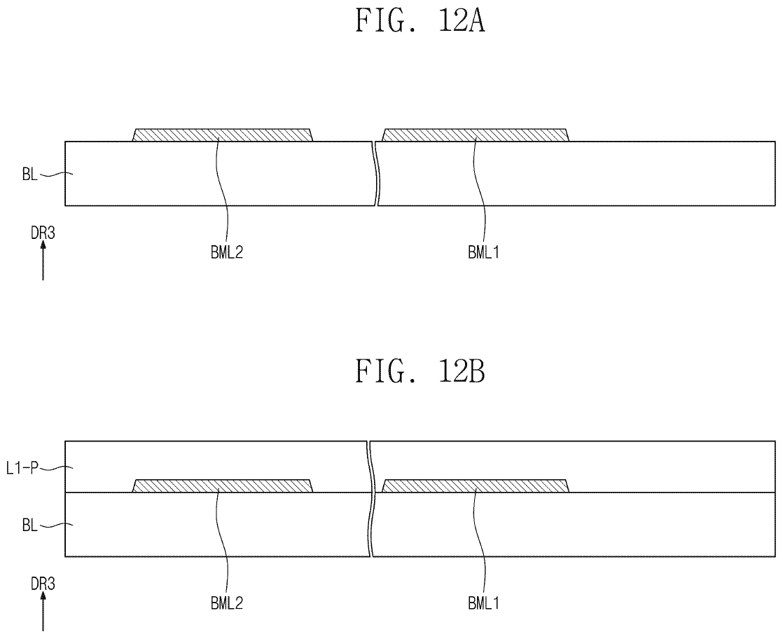

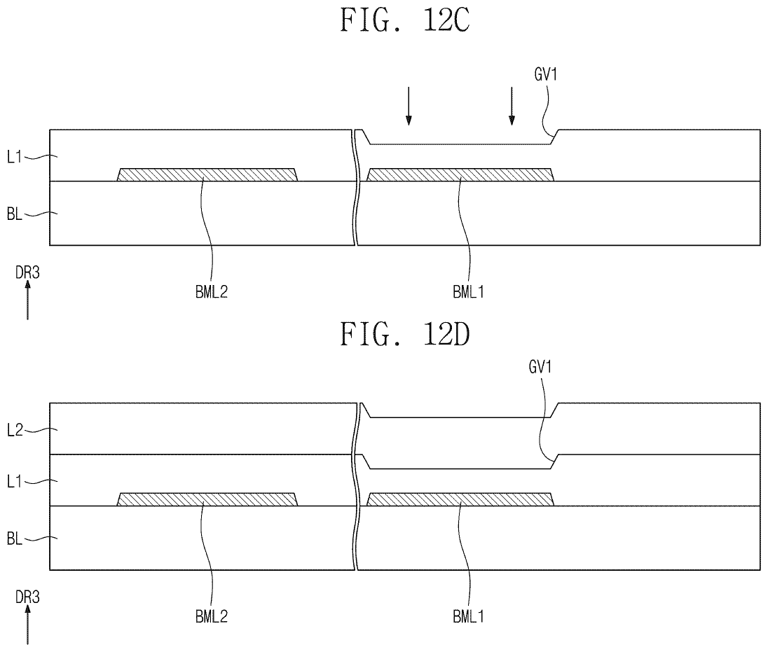

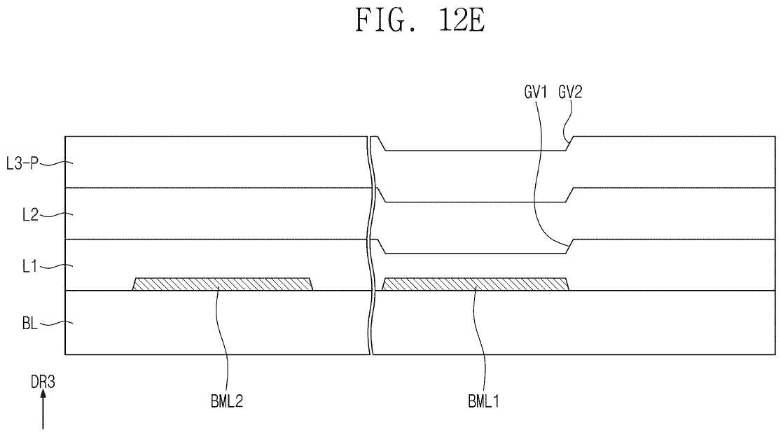

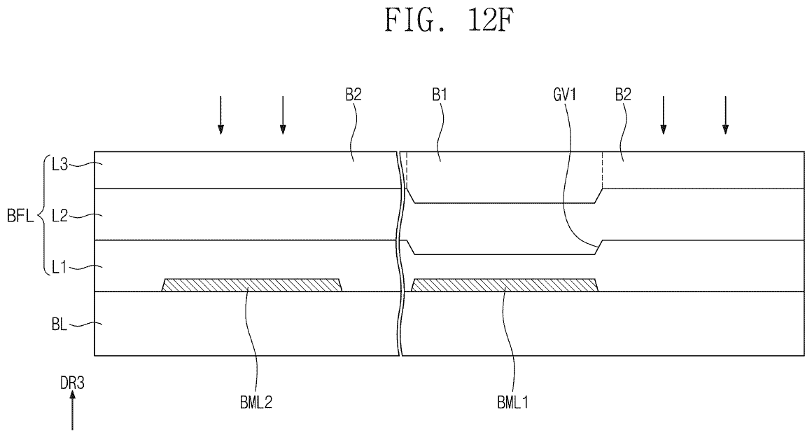

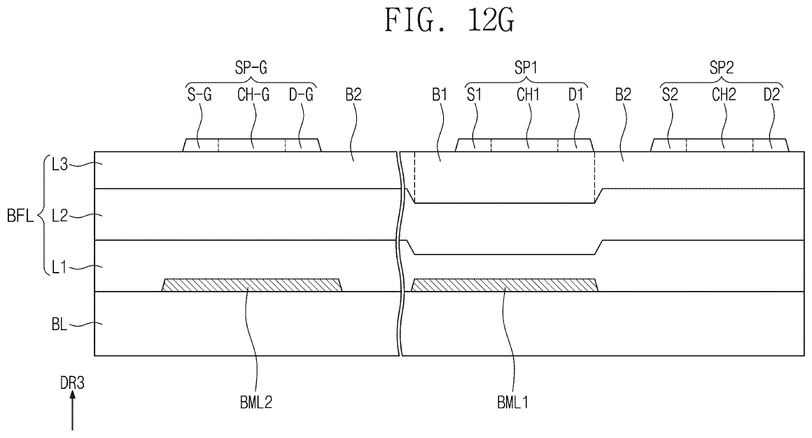

FIGS. 12A to 12G are schematic diagrams showing a manufacturing process of a portion of a display device shown in FIG. 9. Hereinafter, detailed descriptions of the similar configurations to those described in reference to FIGS. 8 to 9 will be omitted.

Referring to FIG. 12A, the base layer BL and shield layers (or conductive layers) BML1 and BML2 on the top surface of the base layer BL may be provided. The shield layers BML1 and BML2 may include a first shield layer BML1 and a second shield layer BML2 spaced apart from each other. The first shield layer BML1 may be disposed in the display area DP-DA (see FIG. 8) and the second shield layer BML2 may be disposed in the non-display area DP-NDA (see FIG. 8). Although not shown, the barrier layer BRL (see FIG. 11) may be further disposed between the base layer BL and the shield layers BML1 and BML2.

The shield layers BML1 and BML2 may be composed of a metal material. Although not shown, the shield layers BML1 and BML2 may be provided entirely on the top surface of the base layer BL and portions the shield layers BML1 and BML2 may be etched. As a result, the shield layers BML1 and BML2 may overlap the semiconductor patterns SP1 and SP-G to be provided thereafter.

Referring to FIG. 12B, a process for providing a preliminary lower layer L1-P provided on the base layer BL and the shield layers BML1 and BML2 may be performed. The top surface of the preliminary lower layer L1-P may be a flat surface. The preliminary lower layer L1-P may be provided by deposition processes. The preliminary lower layer L1-P may include silicon oxide (SiOₓ).

Referring to FIGS. 12B and 12C, a process for etching the preliminary lower layer L1-P to provide the lower layer L1 may be performed. A method for etching the preliminary lower layer L1-P may include photolithography and etching processes. As a result, a first groove GV1 may be formed in the lower layer L1. The first groove GV1 may overlap the first shield BML1 in a plan view. According to an embodiment of the disclosure, the depth of the first groove GV1 may be in a range of about 200 Å to about 300 Å.

Referring to FIG. 12D, a process for providing the intermediate layer L2 on the lower layer L1 may be performed. A groove corresponding to the first groove GV1 may be provided in the intermediate layer L2. The intermediate layer L2 may be provided by deposition processes. The intermediate layer L2 may include silicon nitride (SiNₓ).

Referring to FIG. 12E, a process for providing a preliminary upper layer L3-P on the intermediate layer L2 may be performed. A second groove GV2 corresponding to the first groove GV1 may be provided in the preliminary upper layer L3-P. The preliminary upper layer L3-P may be provided by deposition processes. The preliminary upper layer L3-P and the preliminary lower layer L1-P may include a same material. For example, the preliminary upper layer L3-P may include silicon oxide (SiOₓ).

Referring to FIGS. 12E and 12F, a process for etching the preliminary upper layer L3-P to provide the upper layer L3 may be performed. A method for etching the preliminary upper layer L3-P may include photolithography and etching processes. As a result, the second groove GV2 may be removed from the upper layer L3. For example, the top surface of the upper layer L3 may be a flat surface. An area in which the preliminary upper layer L3-P is etched may be an area non-overlapping the first shield layer BML1.

The third layer L3 may include the first portion B1 and the second portion B2. The first portion B1 may be connected to the area in which the second groove GV2 is provided, and the second portion B2 may correspond to areas except for the second groove GV2. As an embodiment of the disclosure, the first portion B1 may be thicker than the second portion B2. As a result, the reliability of the first transistor T1 (see FIG. 8) to be provided later may be secured, and the reliability of the second transistor T2 (see FIG. 8) to be provided later may be secured.

Referring to FIG. 12G, the semiconductor patterns SP1, SP2 and SP-G may be provided on the buffer layer BFL including the lower layer L1, the intermediate layer L2 and the upper layer L3. Each of the semiconductor patterns SP1, SP2 and SP-G may include an oxide semiconductor.

Although not shown, in a method for providing the semiconductor patterns SP1, SP2 and SP-G, a metal oxide layer may be provided on the buffer layer BFL in a sputtering method or a metal organic chemical vapor deposition (MOCVD) method, and the metal oxide layer may be patterned to provide the semiconductor patterns SP1, SP2 and SP-G. In the process for providing the metal oxide layer, the partial pressure of an oxygen gas to a reaction gas may be in a range of about 50% to about 100%. The reaction gas may be a silane gas, a silane fluoride gas, a nitrogen dioxide gas, or the like.

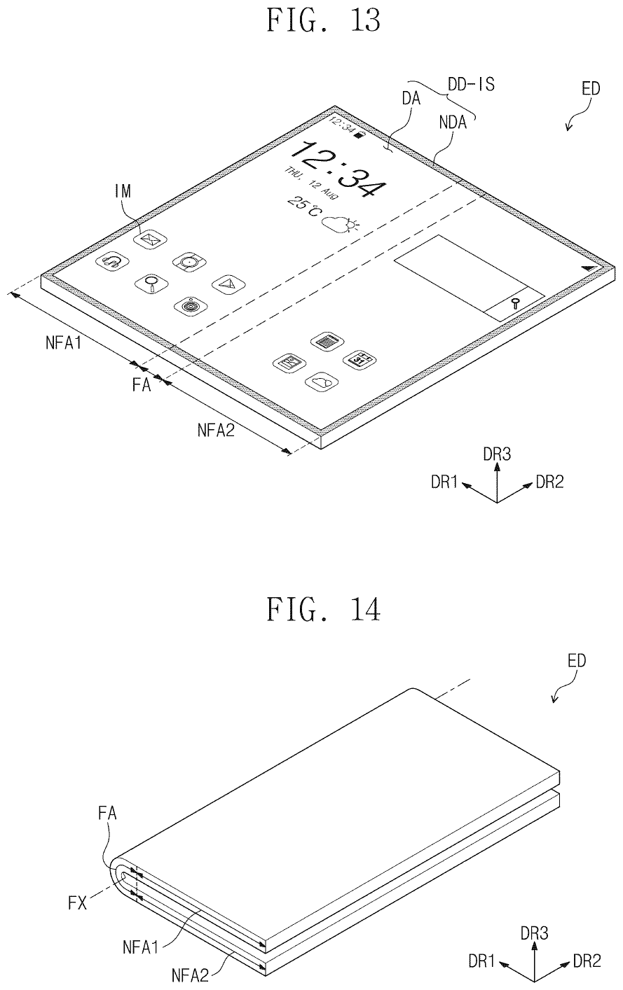

FIG. 13 is a perspective view of an electronic device according to an embodiment of the disclosure. FIG. 14 is a view illustrating a folded state of the electronic device illustrated in FIG. 13.

Referring to FIG. 13, an electronic device ED according to an embodiment of the disclosure may have a rectangular shape having short sides extending in a first direction DR1 and long sides extending in a second direction DR2 intersecting the first direction DR1. However, the disclosure is not limited thereto, and the electronic device ED may have various shapes such as a circular shape and a polygonal shape. The electronic device ED may be flexible.

The electronic device ED may include a folding area FA and multiple non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA, the first non-folding area NFA1, and the second non-folding area NFA2 may be arranged in the first direction DR1.

In FIG. 13, one folding area FA and two non-folding areas NFA1 and NFA2 are illustrated, but the numbers of folding areas FA and the non-folding areas NFA1 and NFA2 are not limited thereto. For example, the electronic device ED may include more than two non-folding areas and multiple folding areas arranged between the non-folding areas.

An upper surface of the electronic device ED may be defined as a display surface DD-IS, and the display surface DD-IS may have the plane defined by the first direction DR1 and the second direction DR2. Images IM generated by the electronic device ED may be provided to a user through the display surface DD-IS.

The display surface DD-IS may include a display area DA and a non-display area NDA adjacent to the display area DA. The display area DA may display an image, and the non-display area NDA may not display an image. The non-display area NDA may surround the display area DA and may define an edge of the electronic device ED printed in a color.

Referring to FIG. 14, the electronic device ED may be a foldable electronic device ED that may be folded or unfolded. For example, the folding area FA may be bendable with respect to a folding axis FX parallel to the second direction DR2, and thus the electronic device ED may be folded. The folding axis FX may be defined as a long axis parallel to the long sides of the electronic device ED. In case that the electronic device ED is folded, the first non-folding area NFA1 and the second non-folding area NFA2 may face each other, and the electronic device ED may be in-folded so that the display surface DD-IS is not exposed to the outside. However, the disclosure is not limited thereto. For example, although not illustrated, the electronic device ED may be out-folded so that the display surface DD-IS is exposed to the outside about the folding axis FX. Further, although not illustrated, the electronic device ED may be in-foldable and out-foldable at the same time.

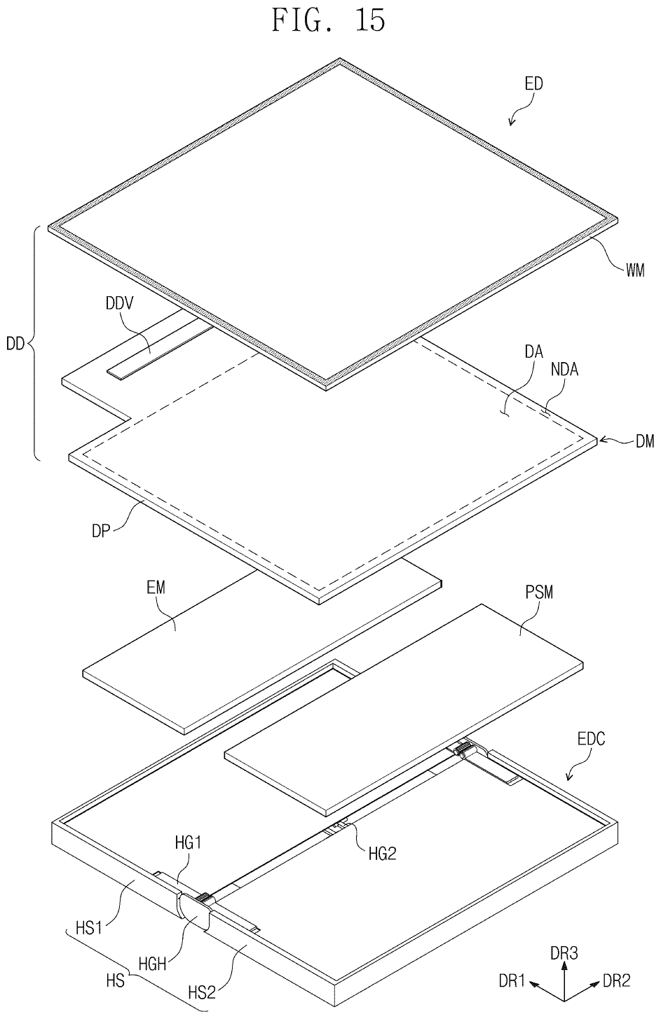

FIG. 15 is an exploded perspective view of the electronic device illustrated in FIG. 13.

Referring to FIG. 15, the electronic device ED may include a display device DD, an electronic module EM, a power supply module PSM, and a hinge module EDC. Although not illustrated, the electronic device ED may further include a mechanical structure (e.g., a hinge) for controlling a folding operation of the display device DD.

The display device DD may generate an image and sense an external input. The display device DD may include a window module WM and a display module DM. The window module WM may provide a front surface of the electronic device ED. The window module WM may be disposed on the display module DM to protect the display module DM. The window module WM may transmit a light generated by the display module DM and provide the light to the user.

The display module DM may include a display panel DP. FIG. 15 illustrates only the display panel DP among laminated structures of the display module DM, but substantially, the display module DM may further include multiple components arranged on an upper side and a lower side of the display panel DP. The display panel DP may include a display area DA and a non-display area NDA corresponding to the display area DA and the non-display area NDA of FIG. 13 of the electronic device ED.

The display module DM may include a data driver DDV disposed in the non-display area NDA of the display panel DP. The data driver DDV may be directly manufactured in the form of a circuit chip and mounted on the display panel in the non-display area NDA. However, the disclosure is not limited thereto, and the data driver DDV may be mounted on a flexible circuit board connected to the display panel DP.

The electronic module EM and the power supply module PSM may be arranged inside the hinge module EDC. Illustratively, FIG. 15 illustrates a state in which the electronic module EM and the power supply module PSM are exposed to the outside from the hinge module EDC. Although not illustrated, the electronic module EM and the power supply module PSM may be connected to each other through a separate flexible circuit board. The electronic module EM may control an operation of the display device DD. The power supply module PSM may supply power to the electronic module EM.

The hinge module EDC may accommodate the display device DD, the electronic module EM, and the power supply module PSM. The hinge module EDC may include first and second housings HS1 and HS2 for folding the display device DD. The first and second housings HS1 and HS2 may extend in the second direction DR2 and may be arranged in the first direction DR1.

The hinge module EDC may include a housing assembly HS. The housing assembly HS may include the first housing HS1 and the second housing HS2 spaced apart from each other in the first direction DR1 and a hinge housing HGH disposed between the first housing HS1 and the second housing HS2. The hinge module EDC may further include hinges HG1 and HG2 for connecting the first and second housings HS1 and HS2, multiple main plates, and multiple moving plates.

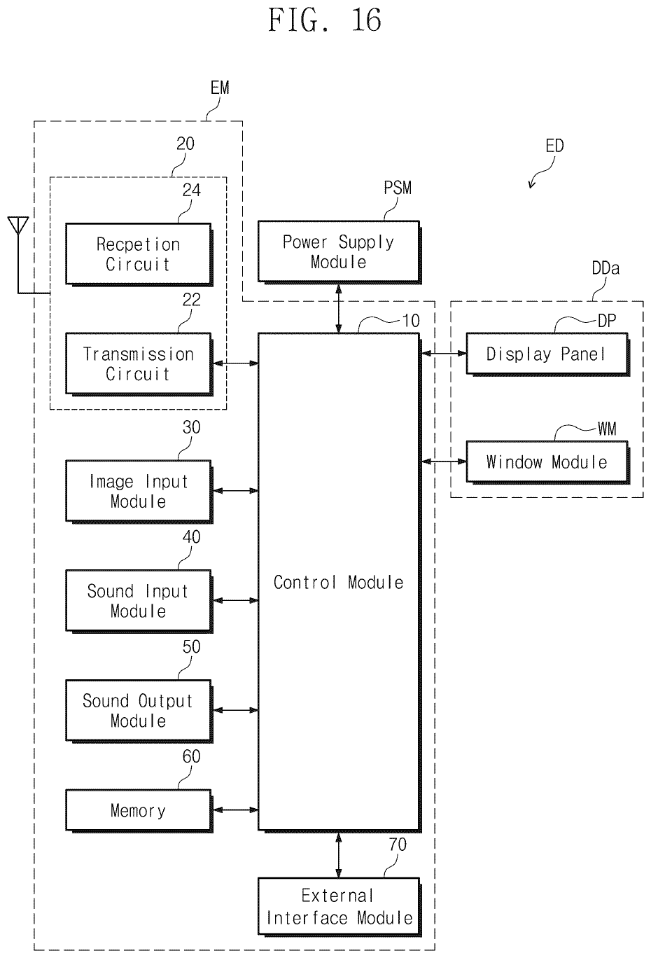

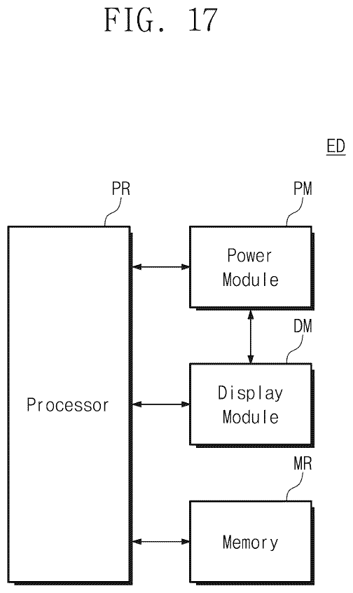

FIG. 16 is a schematic block diagram of the electronic device illustrated in FIG. 13.

Referring to FIG. 16, the electronic device ED may include the electronic module EM, the power supply module PSM, and the display device DDa. The electronic module EM may include a control module 10, a wireless communication module 20, an image input module 30, a sound input module 40, a sound output module 50, a memory 60, an external interface module 70, and the like. The modules may be mounted on a circuit board or may be electrically connected through a flexible circuit board. The electronic module EM may be electrically connected to the power supply module PSM.

The control module 10 may control an overall operation of the electronic device ED. For example, the control module 10 may activate or deactivate the display device DDa in accordance with a user input. The control module 10 may control the image input module 30, the sound input module 40, the sound output module 50, and the like in accordance with the user input. The control module 10 may include at least one microprocessor.

The wireless communication module 20 may transmit/receive a wireless signal to/from another terminal using a Bluetooth or a Wi-Fi. The wireless communication module 20 may transmit/receive a voice signal using a general communication line. The wireless communication module 20 may include a transmission circuit 22 for modulating and transmitting a signal to be transmitted, and a reception circuit 24 for demodulating a received signal.

The image input module 30 may process an image signal and convert the image signal into image data that may be displayed on the display device DDa. The sound input module 40 may receive an external sound signal through a microphone in a recording mode or a voice recognition mode and convert the received external sound signal into electrical voice data. The sound output module 50 may convert sound data received from the wireless communication module 20 or sound data stored in the memory 60 and output the converted sound data to the outside.

The external interface module 70 may serve as an interface connected to an external charger, a wired/wireless data port, and a card socket (e.g., a memory card, a subscriber identity module (SIM)/user interface model (UIM) card).

The power supply module PSM may supply power required for an overall operation of the electronic device ED. The power supply module PSM may include a battery device.

The display device according to the disclosure may include the buffer layer including the upper layer and the transistors disposed on the buffer layer. The thickness of the upper layer overlapping the semiconductor pattern of the driving transistor may be different from the thickness of the upper layer overlapping the semiconductor pattern of the switching transistor. As a result, the threshold voltage (Vth) of the driving transistor moves towards negative (−) voltages, and the threshold voltage (Vth) of the switching transistor moves towards positive (+) voltages. Accordingly, a reliable driving transistor and switching transistor may be provided.

FIG. 17 is a block diagram of an electronic device according to an embodiment. Referring to FIG. 17, an electronic device ED according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information necessary for an operation of the processor PR or the display module DM. When the processor PR executes an application stored in the memory MR, an image data signal and/or an input control signal may be transmitted to the display module DM, and the display module DM may process the received signal and output image information through a display screen.

The power module PM may include a power supply module such as a power adapter or a battery device, and a power conversion module which converts the power supplied by the power supply module and generates power necessary for an operation of the electronic device ED.

At least one of the components of the electronic device ED described above may be included in a display device according to an embodiment. In addition, some of individual modules included as functional in one module may be included in the display device, and others may be provided separately from the display device. For example, the display device may include the display module DM according to an embodiment to be described later. The processor PR, the display module DM, and the power module PM may be provided not in the display device but in another type of device in the electronic device ED.

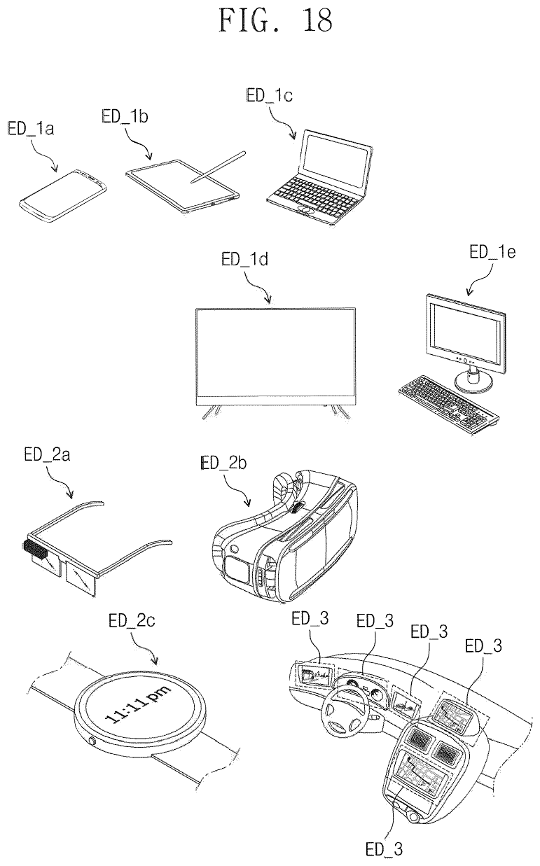

FIG. 18 illustrates schematic views of electronic devices according to various embodiments.

Referring to FIG. 18, various electronic devices according to embodiments, to which a display device is applied, may include not only an electronic device for image display, e.g., a smartphone ED_1a, a tablet PC ED_1b, a laptop computer ED_1c, TV ED_1d, and a monitor for a desk computer ED_1e, but also a wearable electronic device including a display module, e.g., smart glasses ED_2a, a head mounted display ED_2b, and a smart watch ED_2c, and a vehicle electronic device ED_3 including a display module, e.g., a vehicle instrument panel, a center fascia, a center information display (CID) disposed on a dashboard, and a room mirror display.

The display device according to an embodiment may be applied to various electronic devices. The electronic device according to an embodiment may further include a module or device having other additional functions, in addition to the display device.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a circuit layer disposed on a base layer and comprising a buffer layer comprising a plurality of layers and a plurality of pixel transistors disposed on the buffer layer; and
a display layer disposed on the circuit layer and comprising a light-emitting element, wherein
an upper layer forming a top of the plurality of layers comprised in the buffer layer comprises:
a first portion overlapping a first semiconductor pattern of a first pixel transistor among the plurality of pixel transistors in a plan view; and
a second portion overlapping a second semiconductor pattern of a second pixel transistor among the plurality of pixel transistors in a plan view, and
a first thickness of the first portion and a second thickness of the second portion are different from each other.

2. The display device according to claim 1, wherein the buffer layer further comprises a lower layer disposed on the base layer, and an intermediate layer disposed on the lower layer.

3. The display device according to claim 2, wherein
the lower layer comprises:
a third portion overlapping the first semiconductor pattern in a plan view; and
a fourth portion overlapping the second semiconductor pattern in a plan view, and
a third thickness of the third portion and a fourth thickness of the fourth portion are different from each other.

4. The display device according to claim 3, wherein
the first thickness is greater than the third thickness, and
the second thickness is less than the fourth thickness.

5. The display device according to claim 3, wherein a sum of the first thickness and the third thickness and a sum of the second thickness and the fourth thickness are same.

6. The display device according to claim 2, wherein a thickness of the intermediate layer is greater than a thickness of each of the lower layer and the upper layer.

7. The display device according to claim 2, wherein
each of the lower layer and the upper layer comprises silicon oxide, and
the intermediate layer comprises silicon nitride.

8. The display device according to claim 1, wherein
the circuit layer further comprises a barrier layer on the base layer and a conductive layer on the barrier layer, and
the conductive layer overlaps the first semiconductor pattern in a plan view.

9. The display device according to claim 8, further comprising:
a lower conductive layer between the base layer and the barrier layer,
wherein the lower conductive layer overlaps the conductive layer in a plan view.

10. The display device according to claim 1, wherein
the base layer is divided into a display area and a non-display area disposed on at least one side of the display area, and
the circuit layer further comprises a transistor in the non-display area.

11. The display device according to claim 10, wherein
the upper layer further comprises a sub-section overlapping a semiconductor pattern of the transistor in a plan view, and
the first thickness of the first portion and a thickness of the sub-section are different from each other.

12. The display device according to claim 11, wherein
the circuit layer further comprises a conductive layer on the base layer, and
the conductive layer overlaps the semiconductor pattern in a plan view.

13. The display device according to claim 1, wherein the first pixel transistor is a driving transistor, and the second pixel transistor is a switching transistor.

14. The display device according to claim 13, wherein
the first thickness is greater than the second thickness,
the first thickness is in a range of about 500 Å to about 800 Å, and
the second thickness is in a range of about 200 Å to about 500 Å.

15. The display device according to claim 1, wherein each of the first semiconductor pattern and the second semiconductor pattern comprises an oxide semiconductor.

16. An electronic device comprising:
a display device;
an electronic module overlapping the display device in a plan view; and
a housing accommodating the display device, wherein
the display device comprising:
a circuit layer disposed on a base layer and comprising a buffer layer comprising a plurality of layers and a plurality of pixel transistors disposed on the buffer layer; and
a display layer disposed on the circuit layer and comprising a light-emitting element, wherein
an upper layer forming a top of the plurality of layers comprised in the buffer layer comprises:
a first portion overlapping a first semiconductor pattern of a first pixel transistor among the plurality of pixel transistors in a plan view; and
a second portion overlapping a second semiconductor pattern of a second pixel transistor among the plurality of pixel transistors in a plan view, and
a first thickness of the first portion and a second thickness of the second portion are different from each other.

17. A manufacturing method of a display device, comprising:
providing a conductive layer on a base layer;
providing a preliminary lower layer on the base layer and the conductive layer;
first-etching the preliminary lower layer in a first area overlapping the conductive layer in a plan view to form a lower layer;
providing an intermediate layer on the lower layer;
providing a preliminary upper layer on the intermediate layer;
second-etching the preliminary upper layer in a second area non-overlapping the conductive layer in a plan view to form an upper layer; and
providing, on the upper layer, a first semiconductor pattern overlapping the first area and a second semiconductor pattern overlapping the second area in a plan view.

18. The manufacturing method according to claim 17, further comprising:
forming a first groove overlapping the first area in the preliminary lower layer,
wherein a depth of the first groove is in a range of about 200 Å to about 300 Å.

19. The manufacturing method according to claim 18, wherein
a second groove corresponding to the first groove is defined in the preliminary upper layer, and
the second groove is removed by the second-etching.

20. The manufacturing method according to claim 19, wherein
the upper layer comprises:
a first portion overlapping the first semiconductor pattern in a plan view; and
a second portion overlapping the second semiconductor pattern in a plan view, and
a thickness of the second portion is in a range of about 200 Å to about 500 Å after the second-etching.
